(19) United States
(12) Patent Application Publication
(10) Pub. No.: US 2022/0209036 A1
(43) Pub. Date: Jun. 30, 2022

(54) DISCHARGE CONTROL VIA QUANTUM DOTS

(71) Applicant: Nimbus Engineering Inc., San Francisco, CA (US)

(72) Inventor: Alex Diggins, San Francisco, CA (US)

(21) Appl. No.: 17/696,702

(22) Filed: Mar. 16, 2022

Related U.S. Application Data
(63) Continuation of application No. PCT/US2020/051606, filed on Sep. 18, 2020.
(60) Provisional application No. 62/902,786, filed on Sep. 19, 2019.

(51) Int. Cl. H01L 31/055

(52) U.S. Cl. CPC H01L 31/055

(57) ABSTRACT

Disclosed herein are devices and methods for photonic energy storage and on-demand photonic energy discharge. The devices and methods disclosed herein may provide improved temporal control over photonic energy discharge as compared to conventional fluorescent or phosphorescent materials. The devices and methods disclosed herein may provide mechanisms for on-demand photonic energy which may be used to generate light or may converted to electrical energy. A device of this disclosure may comprise a phosphorescent material and a fluorescent material. The phosphorescent material may be configured to absorb photonic energy. The phosphorescent material may store the photonic energy, or the phosphorescent material may transfer the photonic energy to the fluorescent material. The fluorescent material may be configured to emit photonic energy, which may be converted to electrical energy.

### CROSS-REFERENCE

This application is a continuation of International Patent Application No. PCT/US2020/051606, filed Sep. 18, 2020, which claims the benefit of U.S. Provisional Patent Application No. 62/902,786, filed Sep. 19, 2019, which application is entirely incorporated herein by reference.

### BACKGROUND

Especially in an age where so many activities and functions depend on a continuous supply of power, lapses or interruptions in the provision of power may lead to highly undesirable results. These recent years have seen a fast-growing market for readily accessible power, such as in batteries, supercapacitors, fuel cells, and other energy storage devices. Increased utilization of solar power has increased demand for devices configured to absorb and store photonic energy. However, such photonic energy storage devices are often limited in many aspects. For example, a photonic energy storage device may have unregulated release of photonic energy. In some cases, photonic energy storage devices may dissipate charge over time, thereby reducing storage efficiency.

### SUMMARY

Disclosed herein are devices and methods for photonic energy storage and on-demand photonic energy discharge. The devices and methods disclosed herein may provide improved temporal control over photonic energy discharge as compared to conventional fluorescent or phosphorescent materials. The devices and methods disclosed herein may provide mechanisms for on-demand photonic energy which may be used to generate light or may converted to electrical energy.

In various aspects, a photon battery comprises: an optical charging layer comprising (i) phosphorescent material configured to absorb photonic energy from a light source and (ii) fluorescent material configured to conditionally accept photonic energy from the phosphorescent material and emit fluorescence in response to an applied stimulus; and an optical charging layer comprising a photovoltaic cell configured to convert the fluorescence to electrical energy.

In some embodiments, the photon battery further comprises the light source. In some embodiments, the phosphorescent material comprises a phosphor grain. In some embodiments, the phosphorescent material comprises a film or wafer with a maximum thickness of 2 mm. In some embodiments, the fluorescent material comprises a quantum dot. In some embodiments, the fluorescent material comprises a nanorod. In some embodiments, the fluorescent material comprises a quantum well. In some embodiments, the fluorescent material coats or surrounds the phosphorescent material. In some embodiments, the photon battery further comprises a light guide configured to direct the photonic energy from the light source to the optical charging layer. In some embodiments, the stimulus comprises application of an electric field. In some embodiments, the stimulus comprises application of a magnetic field. In some embodiments, the stimulus comprises a temperature change. In some embodiments, the stimulus comprises an applied voltage.

In some embodiments, the photon battery comprises a non-linear optical component disposed between the light source and the optical charging layer. In some embodiments, the non-linear optical component is configured to perform sum-frequency generation. In some embodiments, the phosphorescent material comprises an anisotropic phosphor emitter. In some embodiments, the phosphorescent material comprises a crystal lattice comprising a plurality of phosphors that occupy a specific lattice site.

In various aspects, a method for discharging a photon battery comprises applying the stimulus to a photon battery as described herein. In some embodiments, the stimulus is differentially applied to different portions of the optical charging layer. In some embodiments, the stimulus produces an image. In some embodiments, the image comprises at least 400 pixels. In some embodiments, the at least 400 pixels each comprises a width of at least 30 nm.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the disclosure are set forth with particularity in the appended claims. A better understanding of the features and advantages of the present disclosure will be obtained by reference to the following detailed description that sets forth illustrative embodiments, in which the principles of the disclosure are utilized, and the accompanying drawings of which:

FIG. 1 shows an exemplary photon battery assembly.

FIG. 2 shows a photon battery in communication with an electrical load.

FIG. 3 shows an exemplary photon battery assembly in application.

FIG. 4A illustrates a photon battery assembly with a waveguide.

FIG. 4B illustrates a photon battery assembly with a coating comprising an optical filter.

FIG. 5 illustrates another photon battery assembly with a waveguide.

FIG. 6 illustrates another photon battery assembly with waveguides.

FIG. 7 shows a stack of a plurality of photon battery assemblies.

FIG. 8 shows an exploded view of another configuration for a photon battery assembly stack with hollow core waveguides.

FIG. 9 illustrates a partial cross-sectional side view of the photon battery assembly stack of FIG. 8.

FIG. 10A illustrates a method of controlling energy release from a photon battery.

FIG. 10B illustrates a method of storing energy in a photon battery.

FIG. 11 shows a computer system configured to implement systems and methods of the present disclosure.

FIG. 12A shows an exemplary system for controlled release of photonic energy.

FIG. 12B shows an exemplary photon battery assembly for controlled release of photonic energy.

FIG. 13 illustrates an exemplary change in optical properties in response to an applied electric field.

FIG. 14A illustrates a method for fabricating a photovoltaic panel.

FIG. 14B depicts a junction in a photovoltaic panel.

FIG. 14C depicts a method for fabricating a photovoltaic panel connected by metal contact layers.

FIG. 14D depicts a wafer containing photovoltaic panels with antireflective coatings.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Provided herein are systems and methods for energy storage. While photovoltaic, and thus light to electricity conversion, efficiencies have rapidly improved over recent decades, storing that energy has remained a challenge.

The systems and methods disclosed herein may use phosphorescent material to store energy over a significant duration of time, such as by making use of the time-delayed re-emission properties of phosphorescent material. The phosphorescent material may be energetically coupled to a fluorescent material having spectral properties which may be controlled by one or more external stimuli. For example, the excitation spectrum of the fluorescent material may change in response to an applied electric field. The phosphorescent material may store and/or convert energy with substantial time delay and may transfer energy to the fluorescent material in a stimulus-dependent manner. A light source can provide an initial source of energy to the phosphorescent material in the form of optical energy. For example, the phosphorescent material may absorb optical energy from the light source at a first wavelength. The phosphorescent material may store the optical energy over a significant duration of time in the absence of a stimulus (e.g., application of an electric field). Application of the stimulus, such as the electric field, may cause a shift in the spectral properties of the fluorescent material such that the spectral overlap between the phosphorescent emission and the fluorescent excitation increases. The phosphorescent material may transfer the optical energy to the fluorescent material, for example via Förster resonance energy transfer (FRET), resonance energy transfer (RET), or Dexter transfer, upon application of the stimulus. The fluorescent material may emit optical energy at a second wavelength, such as for receipt by a photovoltaic cell. The light source can be an artificial light source, such as a light emitting diode (LED). A photovoltaic cell can generate electrical power from optical energy, such as from optical energy at the second wavelength that is emitted by the fluorescent material. A waveguide may direct waves, such as the optical energy from the light source at the first wavelength between the light source and the phosphorescent material and/or the optical energy at the second wavelength between the phosphorescent material and the photovoltaic cell. Such waveguides may increase energy density and compactness of the energy storage system. Beneficially, such waveguide may greatly increase efficiency of the time-delayed optical energy transfer between the phosphorescent material, the fluorescent material, the light source, the photovoltaic cell, as well as facilitate efficient use of the available phosphorescent material.

The systems and methods for energy storage disclosed herein may provide superior charging rates to those of conventional chemical batteries, for example, on the order of 100 times faster or more. The systems and methods disclosed herein may provide superior lifetimes to those of conventional chemical batteries, for example, on the order of 10 times more recharge cycles or more. The systems and methods disclosed herein may be portable. The systems and methods disclosed herein may be stable and effective in relatively cold operating temperature conditions. The systems and methods disclosed herein may have superior control of on-demand energy transfer to conventional phosphorescent or fluorescent materials.

Reference will now be made to the figures. It will be appreciated that the figures and features therein are not necessarily drawn to scale.

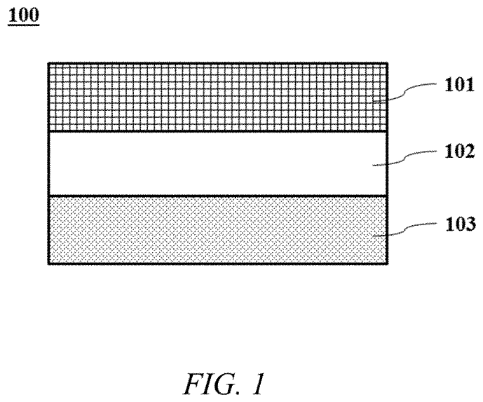

FIG. 1 shows an exemplary photon battery assembly. A photon battery assembly 100 can comprise a light source 101, an optical charging layer 102, and a photovoltaic cell 103. The optical charging layer may be adjacent to both the light source and the photovoltaic cell. For example, the optical charging layer can be sandwiched by the light source and the photovoltaic cell. The optical charging layer can be between the light source and the photovoltaic cell. While FIG. 1 shows the light source, optical charging layer, and photovoltaic cell as a vertical stack, the configuration is not limited as such. For example, the light source, phosphorescent material, and photovoltaic cell can be horizontally stacked or concentrically stacked. The light source and the photovoltaic cell may or may not be adjacent to each other. In some instances, the optical charging layer can be adjacent to a light-emitting surface of the light source. In some instances, the optical charging layer can be adjacent to a light-absorbing surface of the photovoltaic cell.

Regardless of contact between the optical charging layer 102 and light source 101, the optical charging layer and the light source may be in optical communication. For example, as described elsewhere herein, the optical charging layer and the light source may be in optical communication via a waveguide. Regardless of contact between the optical charging layer and photovoltaic cell 103, the optical charging layer and the photovoltaic cell may be in optical communication. For example, as described elsewhere herein, the optical charging layer and the photovoltaic cell may be in optical communication via a waveguide. In some instances, the same waveguide may be configured to facilitate optical communication between the optical charging layer and the photovoltaic cell and between the optical charging layer and the light source.

The optical charging layer 102 may or may not be contacting the light source 101. If the optical charging layer and the light source are in contact, the optical charging layer can interface a light-emitting surface of the light source. The optical charging layer and the light source can be coupled or fastened together at the interface, such as via a fastening mechanism. In some instances, a support carrying the light source and/or a support carrying the optical charging layer may be coupled or fastened together at the interface. Examples of fastening mechanisms may include, but are not limited to, form-fitting pairs, hooks and loops, latches, staples, clips, clamps, prongs, rings, brads, rubber bands, rivets, grommets, pins, ties, snaps, velcro, adhesives, tapes, a combination thereof, or any other types of fastening mechanisms. In some instances, the optical charging layer may have adhesive and/or cohesive properties and adhere to the light source without an independent fastening mechanism. For example, the optical charging layer may be painted or coated on the light-emitting surface of the light source. In some instances, the optical charging layer may be coated onto primary, secondary, and/or tertiary optics of the light source. In some instances, the optical charging layer may be coated onto other optical elements of the light source. The optical charging layer and the light source can be permanently or detachably fastened together. For example, the optical charging layer and the light source can be disassembled from and reassembled into the photon battery assembly 100 without damage (or with minimal damage) to the optical charging layer and/or the light source. Alternatively, while in contact, the optical charging layer and the light source may not be fastened together.

If the optical charging layer 102 and the light source 101 are not in contact, the optical charging layer can otherwise be in optical communication with a light-emitting surface of the light source, such as via a waveguide. For example, the optical charging layer can be positioned in an optical path of light emitted by the light-emitting surface of the light source. In some instances, there can be an air gap between the optical charging layer and the light source. In some instances, there can be another intermediary layer between the optical charging layer and the light source. The intermediary layer can be air or other fluid. The intermediary layer can be a light guide or another layer of optical elements (e.g., lens, reflector, diffusor, beam splitter, etc.). In some instances, there can be a plurality of intermediary layers between the optical charging layer and the light source.

The optical charging layer 102 may or may not be contacting the photovoltaic cell 103. If the optical charging layer and the photovoltaic cell are in contact, the optical charging layer can interface a light-absorbing surface of the photovoltaic cell. The optical charging layer and the photovoltaic cell can be coupled or fastened together at the interface, such as via a fastening mechanism. In some instances, a support carrying the photovoltaic cell and/or a support carrying the optical charging layer may be coupled or fastened together at the interface. In some instances, the optical charging layer may have adhesive properties and adhere to the photovoltaic cell without an independent fastening mechanism. For example, the optical charging layer may be painted or coated on the light-absorbing surface of the photovoltaic cell. In some instances, the optical charging layer may be coated onto primary, secondary, and/or tertiary optics of the photovoltaic cell. In some instances, the optical charging layer may be coated onto other optical elements of the photovoltaic cell. The optical charging layer and the photovoltaic cell can be permanently or detachably fastened together. For example, the optical charging layer and the photovoltaic cell can be disassembled from and reassembled into the photon battery assembly 100 without damage (or with minimal damage) to the optical charging layer and/or the photovoltaic cell. Alternatively, while in contact, the optical charging layer and the photovoltaic cell may not be fastened together.

If the optical charging layer 102 and the photovoltaic cell 103 are not in contact, the optical charging layer can otherwise be in optical communication with a light-absorbing surface of the photovoltaic cell. For example, the light-absorbing surface of the photovoltaic cell can be positioned in an optical path of light emitted by the optical charging layer. In some instances, there can be an air gap between the optical charging layer and the photovoltaic cell. In some instances, there can be another intermediary layer between the optical charging layer and the photovoltaic cell. The intermediary layer can be air or other fluid. The intermediary layer can be a light guide, light concentrator, or another layer of optical elements (e.g., lens, reflector, diffusor, beam splitter, etc.). In some instances, there can be a plurality of intermediary layers between the optical charging layer and the photovoltaic cell.

In some instances, the photon battery assembly 100 can be assembled or disassembled, such as into the light source 101, optical charging layer 102, or the photovoltaic cell 103 independently, or into sub-combinations thereof. In some instances, the photon battery assembly can be assembled or disassembled without damage to the different parts or with minimal damage to the different parts.

In some instances, the photon battery assembly 100 can be housed in a shell, outer casing, or other housing. The photon battery assembly 100, and/or shell thereof can be portable. For example, the photon battery assembly can have a maximum dimension of at most about 1 meter (m), 90 centimeters (cm), 80 cm, 70 cm, 60 cm, 50 cm, 45 cm, 40 cm, 35 cm, 30 cm, 25 cm, 20 cm, 15 cm, 10 cm, 9 cm, 8 cm, 7 cm, 6 cm, 5 cm, or smaller. A maximum dimension of the photon battery assembly may be a dimension of the photon battery assembly (e.g., length, width, height, depth, diameter, etc.) that is greater than the other dimensions of the photon battery assembly. Alternatively, the photon battery assembly may have greater maximum dimensions. For example, a photon battery assembly having a higher energy storage capacity can have larger dimensions and may not be portable.

The light source 101 can be an artificial light source, such as a light emitting diode (LED) or other light emitting device. For example, the light source can be a laser or a lamp. The light source can be a plurality of light emitting devices (e.g., a plurality of LEDs). In some instances, the light source can be arranged as one LED. In some instances, the light source can be arranged as rows or columns of multiple LEDs. The light source can be arranged as arrays or grids of multiple columns, rows, or other axes of LEDs. The light source can be a combination of different light emitting devices. A light emitting surface of the light source can be planar or non-planar. A light emitting surface of the light source can be substantially flat, substantially curved, or form another shape.

The light source can be supported by rigid and/or flexible supports. For example, the supports can direct the light emitted by the light source to be directional or non-directional. In some instances, the light source can comprise primary and/or secondary optical elements. In some instances, the light source can comprise tertiary optical elements. In some instances, the light source can comprise other optical elements at other levels or layers (e.g., lens, reflector, diffusor, beam splitter, etc.). The light source can be configured to convert electrical energy to optical energy. For example, the light source can be powered by an electrical power source, which may be external or internal to the photon battery assembly 100. The light source can be configured to emit optical energy (e.g., as photons), such as in the form of electromagnetic waves. In some instances, the light source can be configured to emit optical energy at a wavelength or a range of wavelengths that is capable of being absorbed by the phosphorescent material 102. For example, the light source can emit light at wavelengths in the ultraviolet range (e.g., 10 nanometers (nm) to 400 nm). In some instances, the light source can emit light at other wavelengths or ranges of wavelengths in the electromagnetic spectrum (e.g., infrared, visible, ultraviolet, x-rays, etc.).

In some instances, the light source 101 can be a natural light source (e.g., sun light), in which case the phosphorescent material 102 in the photon battery assembly 100 may be exposed to the natural light source to absorb such natural light.

The optical charging layer 102 can absorb optical energy at a first wavelength (or first wavelength range) and emit optical energy at a second wavelength (or second wavelength range) after a substantial time delay. The second wavelength can be a different wavelength than the first wavelength. The optical energy at the first wavelength that is absorbed by the optical charging layer can be at a higher energy level than the optical energy at the second wavelength that is emitted by the optical charging layer. The second wavelength can be greater than the first wavelength. In an example, the optical charging layer can absorb energy at ultraviolet range wavelengths (e.g., 10 nm to 400 nm) and emit energy at visible range wavelengths (e.g., 400 nm to 700 nm). For example, the optical charging layer can absorb blue photons and, after a time delay, emit green photons. The optical charging layer absorb optical energy (e.g., photons) at other wavelengths (or ranges of wavelengths) and emit optical energy at other wavelengths (or ranges of wavelengths), such as in the electromagnetic spectrum (e.g., infrared, visible, ultraviolet, x-rays, etc.) wherein the energy emitted is at a lower energy level than the energy absorbed. A rate of emission of optical energy by the optical charging layer can be slower than a rate of absorption of optical energy by the phosphorescent material. The rate of emission of optical energy by the optical charging layer can be controlled by an external stimulus. The rate of emission of optical energy may be low in the absence of the stimulus and increase in the presence of the stimulus. The rate of emission of optical energy may be high in the absence of the stimulus and decrease in the presence of the stimulus. Optical energy may be stored when the rate of emission is low and may be released when the rate of emission is high. One advantage of stimulus-controlled emission of optical energy is the ability to store or release optical energy on-demand.

The optical charging layer 102 can be crystalline, solid, liquid, ceramic, in powder form, granular or other particle form, liquid form, or in any other shape, state, or form. The optical charging layer may comprise a phosphorescent material and a fluorescent material. The phosphorescent material may absorb optical energy at a first wavelength and emit optical energy at a second wavelength. The second wavelength may be longer than the first wavelength. In some instances, the phosphorescent material may store the optical energy. In some instances, the phosphorescent material may transfer the optical energy to a fluorescent material. The phosphorescent material can comprise long-lasting phosphors. The phosphorescent material may comprise zinc sulfide (ZnS). In an example, the phosphorescent material can comprise strontium aluminate doped with europium (e.g., SrAl₂O₄:Eu). Some other examples of phosphorescent material can include, but are not limited to, zinc gallogermanates (e.g., Zn₃Ga₂Ge₂O₁₀:0.5% Cr³⁺), zinc sulfide doped with copper and/or cobalt (e.g., ZnS:Cu, Co), strontium aluminate doped with other dopants, such as europium, dysprosium, and/or boron (e.g., SrAl₂O₄:Eu²⁺, Dy³⁺, B³⁺), calcium aluminate doped with europium, dysprosium, lithium, magnesium, manganese, and/or neodymium (e.g., CaAl₂O₄:Eu²⁺, Dy³⁺, Nd³⁺), yttrium oxide sulfide doped with europium, magnesium, and/or titanium, (e.g., Y₂O₂S:Eu³⁺, Mg²⁺, Ti⁴⁺, and zinc gallogermanates (e.g., Zn₃Ga₂Ge₂O₁₀:0.5% Cr³⁺).

In some instances, the phosphorescent material may be provided in granular or other particle form. In an example, the grain or particle may have a maximum diameter of between about 1 and about 5 micrometers. In another example, the grain or particle may have a diameter of between about 1 nanometer (nm) and about 100 nm. In some instances, the grain or particle may have a minimum diameter of at least about 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, 5.0 micrometers or more. Alternatively or in addition, the grain or particle may have a maximum diameter of at most about 5.0, 4.9, 4.8, 4.7, 4.6, 4.5, 4.4, 4.3, 4.2, 4.1, 4.0, 3.9, 3.8, 3.7, 3.6, 3.5, 3.4, 3.3, 3.2, 3.1, 3.0, 2.9, 2.8, 2.7, 2.6, 2.5, 2.4, 2.3, 2.2, 2.1, 2.0, 1.9, 1.8, 1.7, 1.6, 1.5, 1.4, 1.3, 1.2, 1.1, 1.0 micrometers or less. In some instances, the grain or particle may have a minimum diameter of at least about 1, 2, 3, 4, 5, 6, 7, 8, 9, 10, 11, 12, 13, 14, 15, 16, 17, 18, 19, 20, 30, 40, 50, 60, 70, 80, 90, 100 nm or more. Alternatively or in addition, the grain or particle may have a maximum diameter of at most about 900, 800, 700, 600, 500, 400, 300, 200, 100, 90, 80, 70, 60, 50, 40, 30, 20, 10 nm or less.

In some instances, the afterglow (e.g., emitted optical energy) emitted by the phosphorescent material can last at least about 1 hour (hr), 2 hr, 3 hr, 4 hr, 5 hr, 6 hr, 7 hr, 8 hr, 9 hr, 10 hr, 11 hr, 12 hr, 1 day, 2 days, 3 days, 4 days, 1 week, 2 weeks, 3 weeks, or longer. In some instances, the phosphorescent material can store and/or discharge energy for at least about 1 hr, 2 hr, 3 hr, 4 hr, 5 hr, 6 hr, 7 hr, 8 hr, 9 hr, 10 hr, 11 hr, 12 hr, 1 day, 2 days, 3 days, 4 days, 1 week, 2 weeks, 3 weeks, or longer. Alternatively, the afterglow emitted by the phosphorescent material (or energy stored by the phosphorescent material) can last for shorter durations.

In some instances, the phosphorescent material 102 may absorb optical energy at the first wavelength from any direction. In some instances, the phosphorescent material may emit optical energy at the second wavelength in any direction (e.g., from a surface of the phosphorescent material). In some instances, the phosphorescent material 102 may comprise an isotropic absorption profile. Conversely, a phosphorescent material may comprise an anisotropic phosphor emitter (e.g., a phosphor with an anisotropic absorbance and/or emission profile). A phosphorescent material may predominantly absorb light along a particular axis or within a particular plane (relative to an axis of the phosphorescent molecule or material). A phosphorescent material may be dichroic. A phosphorescent material may predominantly emit light along a particular axis or within a particular plane. The axis or plane along which a phosphorescent material absorbs light may be identical to or different than the axis or plane in which the phosphorescent material emits. For example, a phosphorescent material may primarily absorb and emit light along axes offset by 90°. Absorption directionality may be wavelength specific. For example, a phosphorescent material could comprise two absorption bands separated by an energy (e.g., 0.4 eV) and polarized along axes offset by an angle (e.g., 30°). A phosphorescent material may comprise multiple absorption bands comprising intersystem crossings to a stable excited state.

Phosphorescent materials with anisotropic absorption and emission profiles can allow battery designs in which the light source 101, optical charging layer 102, and photovoltaic cell 103 are disposed at an angle. In some cases, the light source, optical charging layer, and photovoltaic cell may offset at least 10 degrees from parallel. In some cases, the light source, optical charging layer, and photovoltaic cell may offset at least 30 degrees from parallel. In some cases, the light source, optical charging layer, and photovoltaic cell may offset at least 50 degrees from parallel. In some cases, the light source, optical charging layer, and photovoltaic cell may offset at least 75 degrees from parallel. In some cases, the light source, optical charging layer, and photovoltaic cell may offset at least 90 degrees from parallel. In some cases, the light source, optical charging layer, and photovoltaic cell may offset by at least 100 degrees from parallel. In some cases, the light source, optical charging layer, and photovoltaic cell may offset at least 120 degrees from parallel. In some cases, the light source, optical charging layer, and photovoltaic cell may offset at least 150 degrees from parallel.

In some instances, the energy absorbed by the phosphorescent material in the optical charging layer 102 may be transferred to another material, for example a fluorescent material. The energy absorbed by the phosphorescent material may be transferred via Forster resonance energy transfer (FRET), resonance energy transfer (RET), bioluminescence energy transfer (BRET), Dexter transfer, non-radiative energy transfer, or the like. Energy transfer from the phosphorescent material to the fluorescent material may be contingent on the presence or absence of a stimulus. In some instances, energy transfer may be contingent on application of an electric field. For example, the phosphorescent material may store the absorbed energy in the absence of the applied electric field and may transfer the absorbed energy to the fluorescent material in the presence of the applied electric field. In some instances, application of an electric field may increase the efficiency of the energy transfer between the phosphorescent material and the fluorescent material. Energy transfer efficiency between the phosphorescent material and the fluorescent material may be distance-dependent. In some instances, the distance at which energy transfer efficiency between the fluorescent material and the phosphorescent material may be a Forster radius. In some instances, the Forster radius may be at most about 1 nanometer (nm), 2 nm, 3 nm, 4 nm, 5 nm, 6 nm, 7 nm, 8 nm, 9 nm, 10 nm, 15 nm, 20 nm, 25 nm, 50 nm, 100 nm, 200 nm, 300 nm, 400 nm, 500 nm, 600 nm, 700 nm, 800 nm, 900 nm, or more. In some instances, the Forster radius may be at most about 10 nm, 15 nm, 20 nm, 25 nm, 50 nm, 100 nm, 200 nm, 300 nm, 400 nm, 500 nm, 600 nm, 700 nm, 800 nm, 900 nm, 1 μm, 2 μm, 3 μm, 4 μm, 5 μm, 6 μm, 7 μm, 8 μm, 9 μm, 10 μm, or less. In some instances, the Förster radius may change in response to a stimulus, for example an applied electric field.

The fluorescent material may be in contact with or in close proximity to the phosphorescent material in the optical charging layer 102. If the fluorescent material and the phosphorescent material are not in contact, the fluorescent material may be otherwise in optical communication with the phosphorescent material. The fluorescent material may be positioned within a Förster radius of the phosphorescent material, for example the Förster radius of the phosphorescent material and fluorescent material FRET pair in the presence of a stimulus, or the Förster radius of the phosphorescent material and fluorescent material FRET pair in the absence of a stimulus. The fluorescent material may be positioned at most about 1 nm, 2 nm, 3 nm, 4 nm, 5 nm, 6 nm, 7 nm, 8 nm, 9 nm, 10 nm, 15 nm, 20 nm, 25 nm, 50 nm, 100 nm, 200 nm, 300 nm, 400 nm, 500 nm, 600 nm, 700 nm, 800 nm, 900 nm, or less from the phosphorescent material, as measured from a surface of the fluorescent material to a surface of the phosphorescent material. The fluorescent material may surround the phosphorescent material. For example, the fluorescent material may coat the phosphorescent material. In some instances, the fluorescent material may comprise particles. In some instances, particles of the fluorescent material may surround or coat the phosphorescent material. In some instances, particles of the fluorescent material may surround or coat particles or grains of the phosphorescent material. The distance between the fluorescent material and the phosphorescent material may be limited by the diameter of the grains or particles. In some instance the sum of the diameters of the phosphorescent material grains or particles and the fluorescent material grains or particles may be a minimum of at least about 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, 5.0 micrometers or more. Alternatively or in addition, the sum of the diameters of the phosphorescent material grains or particles and the fluorescent material grains or particles may be a maximum of at most about 5.0, 4.9, 4.8, 4.7, 4.6, 4.5, 4.4, 4.3, 4.2, 4.1, 4.0, 3.9, 3.8, 3.7, 3.6, 3.5, 3.4, 3.3, 3.2, 3.1, 3.0, 2.9, 2.8, 2.7, 2.6, 2.5, 2.4, 2.3, 2.2, 2.1, 2.0, 1.9, 1.8, 1.7, 1.6, 1.5, 1.4, 1.3, 1.2, 1.1, 1.0 micrometers or less.

The fluorescent material may absorb optical energy at a first wavelength and emit optical energy at a second wavelength. The first wavelength may be shorter than the second wavelength. In some instances, the time between absorption and emission of the optical energy (e.g., the fluorescence lifetime) is between about 3 nanoseconds (ns) and about 30 ns. The fluorescent material may be a semiconductor. In some instances, the fluorescent material may comprise zinc sulfide (ZnS). The fluorescent material may comprise one or more of ZnS, cadmium sulfide (CdS), cadmium selenide (CdSe), zinc selenide (ZnSe), lead sulfide (PbS), lead selenide (PbSe), cadmium telluride (CdTe), indium arsenide (InAs), and indium phosphide (InP). In some instances, the fluorescent material may comprise a first material coated with a second material. For example, the fluorescent material may comprise a CdSe quantum dot coated with CdS. In some instances, the fluorescent material may be provided in particle form. For example, the fluorescent material may comprise a semiconducting quantum dot. In some instances, the fluorescent particle may have a diameter between about 1 nm and about 10 nm. In some instances, the fluorescent material may comprise a nanorod. In some instances, the fluorescent material may comprise a quantum well. The fluorescent particle may have any shape, size, or form. The fluorescent particle (e.g., quantum dot or nanorod) may have a minimum diameter of at least about 0.5, 0.6, 0.7, 0.8, 0.9, 1, 1.1, 1.2, 1.3, 1.4, 1.5, 2, 3, 4, 5, 6, 7, 8, 9, 10, 11, 12, 13, 14, 15, 20, 30, 40, 50 nm or more. Alternatively or in addition, the fluorescent particle may have a maximum diameter of at most about 100, 90, 80, 70, 60, 50, 40, 30, 20, 10, 9, 8, 7, 6, 5, 4, 3, 2, 1 nm or less. The fluorescent particle may comprise an absorption bandwidth of 2 nm, 3 nm, 4 nm, 5 nm, 6 nm, 8 nm, 10 nm, 12 nm, 15 nm, 20 nm, 25 nm, 30 nm, 40 nm, 50 nm, 60 nm, 80 nm, 100 nm, 120 nm, 150 nm, 200 nm or more. The fluorescent particle may comprise an absorption band centered at 400 nm, 420 nm, 440 nm, 460 nm, 480 nm, 500 nm, 520 nm, 540 nm, 560 nm, 580 nm, 600 nm, 620 nm, 640 nm, 660 nm, 680 nm, 700 nm, 720 nm, 740 nm, 760 nm, 780 nm, 800 nm, 820 nm, 840 nm, 860 nm, 880 nm, 900 nm or greater. The fluorescent particle may comprise a fluorescence band centered at 480 nm, 500 nm, 520 nm, 540 nm, 560 nm, 580 nm, 600 nm, 620 nm, 640 nm, 660 nm, 680 nm, 700 nm, 720 nm, 740 nm, 760 nm, 780 nm, 800 nm, 820 nm, 840 nm, 860 nm, 880 nm, 900 nm, 920 nm, 940 nm, 960 nm, 980 nm, 1050 nm, 1100 nm or greater.

The optical charging layer 102 may comprise a FRET donor and a FRET acceptor. In an example, the phosphorescent material may be the FRET donor and the fluorescent material may be the FRET acceptor. The emission spectrum of the phosphorescent material may overlay with the excitation spectrum of the fluorescent material. In some instances, optical energy may be absorbed by the phosphorescent material at a first wavelength, transferred to the fluorescent material via FRET, and emitted by the fluorescent material at a second wavelength. The first wavelength may be shorter (e.g., higher energy) than the second wavelength. Transfer of the optical energy from the phosphorescent material to the fluorescent material may occur with a certain transfer efficiency. In some instances, the transfer efficiency may be at least about 1%, 5%, 10%, 15%, 20%, 30%, 40%, 50%, 60%, 70%, 80%, 90%, or more. Alternatively or in addition, the transfer efficiency may be at most about 99%, 95%, 90%, 80%, 70%, 60%, 50%, 40%, 30%, 20%, 10%, 5%, 1%, or less. The transfer efficiency may depend on the presence or absence of a stimulus. In an example, the transfer efficiency may increase in the presence of a stimulus. In another example, the transfer efficiency may decrease in the presence of a stimulus. The stimulus may be an applied electric field. The transfer efficiency may increase by about 1-fold, 2-fold, 3-fold, 4-fold, 5-fold, 6-fold, 7-fold, 8-fold, 9-fold, 10-fold, 20-fold, 30-fold, 40-fold, 50-fold, 60-fold, 70-fold, 80-fold, 90-fold, 100-fold, or more in response to the applied electric field. The transfer efficiency may decrease by about 1-fold, 2-fold, 3-fold, 4-fold, 5-fold, 6-fold, 7-fold, 8-fold, 9-fold, 10-fold, 20-fold, 30-fold, 40-fold, 50-fold, 60-fold, 70-fold, 80-fold, 90-fold, 100-fold, or more in response to the applied electric field.

The optical charging layer 102 may further comprise a mechanism for applying a stimulus to the optical charging layer. For example, the optical charging layer may further comprise a mechanism to apply an electric field to the optical charging layer. The mechanism to apply the electric field may comprise an anode, a cathode, and/or a voltage source. A voltage may be applied across all or part of the optical charging layer, thereby generating the applied electric field. In some instances, the applied voltage may be turned on and off or may be increased or decreased. In some instances, the applied voltage may be at least about 10, 20, 30, 40, 50, 60, 70, 80, 90, 100, 200, 300, 400, 500 millivolts (mV) or more. In some instances, the applied voltage may be at most about 10, 9, 8, 7, 6, 5, 4, 3, 2, 1, 0.9, 0.8, 0.7, 0.6, 0.5, 0.4, 0.3, 0.2, 0.1 Volts (V) or less. In some instances, the applied voltage may be at least about 1, 2, 3, 4, 5, 10, 20, 30, 40, 50, 100, 200, 300, 400, 500 Volts (V) or more. In some instances, the applied voltage may be at most about 1000, 900, 800, 700, 600, 500, 400, 300, 200, 100, 90, 80, 70, 60, 50 Volts (V) or more. The applied voltage may be sufficient to generate a significant quantum confined Stark effect (QCSE) in the fluorescent material. The applied voltage may be configured to compensate for destructive interference with the electric field due to polarization of an internal dipole of the fluorescent material or the phosphorescent material based on a dielectric constant of the fluorescent material or the phosphorescent material.

The assembly 100 can comprise one or a plurality of photovoltaic cells (e.g., photovoltaic cell 103) that are electrically connected in series and/or in parallel. The photovoltaic cell 103 can be a panel, cell, module, and/or other unit. For example, a panel can comprise one or more cells all oriented in a plane of the panel and electrically connected in various configurations. For example, a module can comprise one or more cells electrically connected in various configurations. The photovoltaic cell 103, or solar cell, can be configured to absorb optical energy and generate electrical power from the absorbed optical energy. In some instances, the photovoltaic cell can be configured to absorb optical energy at a wavelength or a range of wavelengths that is capable of being emitted by the optical charging layer 102. The photovoltaic cell can have a single band gap that is tailored to the wavelength (or range of wavelengths) of the optical energy that is emitted by the phosphorescent material. Beneficially, this may increase the efficiency of the energy storage system of the photon battery assembly 100. For example, for strontium aluminate doped with europium as the phosphorescent material, the photovoltaic cell can have a band gap that is tailored to the green light wavelength (e.g., 500-520 nm). Similarly, the light source 101 can be tailored to emit ultraviolet range wavelengths (e.g., 20 nm to 400 nm). Alternatively, the photovoltaic cell can be configured to absorb optical energy at other wavelengths (or ranges of wavelengths) in the electromagnetic spectrum (e.g., infrared, visible, ultraviolet, x-rays, etc.).

The photovoltaic cell 103 may have any thickness. For example, the photovoltaic cell may have a thickness of about 20 micrometers. In some instances, the photovoltaic cell may have a thickness of at least about 10, 11, 12, 13, 14, 15, 16, 17, 18, 19, 20, 21, 22, 23, 24, 25, 26, 27, 28, 29, 30, 40, 50, 60, 70, 80, 90, 100 micrometers or more. Alternatively or in addition, the photovoltaic cell may have a thickness of at most about 100, 90, 80, 70, 60, 50, 40, 30, 29, 28, 27, 26, 25, 24, 23, 22, 21, 20, 19, 18, 17, 16, 15, 14, 13, 12, 11, 10 micrometers or less.

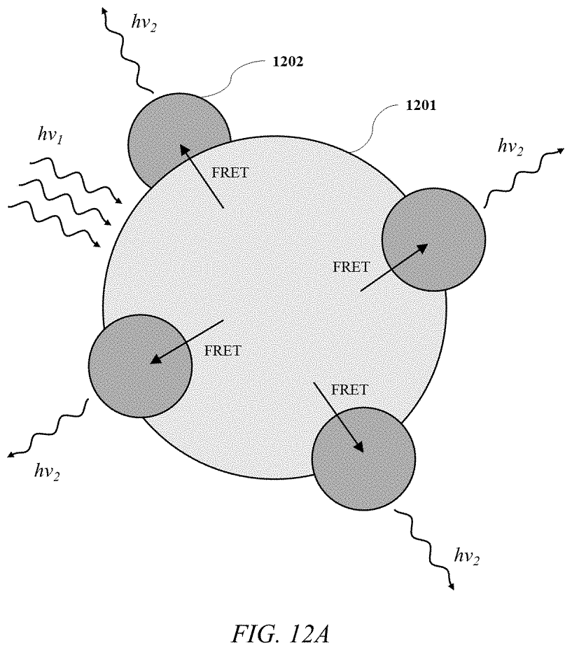

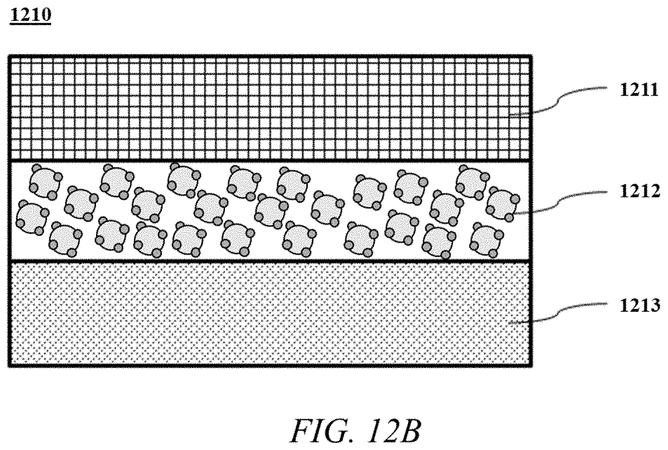

FIG. 12A shows an exemplary configuration of phosphorescent material and fluorescent material. In some aspects, particles of fluorescent material 1202 may surround particles or grains of phosphorescent material 1201. In some aspects, the fluorescent material may surround or coat particles or grains of phosphorescent material. The fluorescent material may or may not be in contact with the phosphorescent material. Regardless of contact between the fluorescent material and the phosphorescent material, the fluorescent material may be in optical communication with the phosphorescent material. Energy transfer between the phosphorescent material and fluorescent material may be radiationless (e.g., the energy transfer may comprise quantum tunneling) or involve phosphor emission. The phosphorescent material and the fluorescent material may be further arranged in an optical charging layer, as described elsewhere herein.

The optical charging layer may comprise a feature, such as a rod (e.g., nanorods), well, trench, wall, or ridge, that imparts a particular separation between a phosphorescent and a fluorescent material. For example, a nanorod may be fabricated with phosphorescent and fluorescent materials at opposite ends, thereby defining a separation distance between the phosphor donor and fluorophore acceptor. Similarly, a phosphorescent material may be patterned on the opposite side of a ridge or well from a fluorescent material. A feature may be transparent or translucent, and thereby transmit light from a phosphorescent material to a fluorescent material. Furthermore, a feature may filter or route light of specific wavelengths.

The phosphorescent material 1201 may absorb optical energy at a first wavelength (hv₁) from a light source. In some aspects, the phosphorescent material may conditionally transfer the optical energy to the fluorescent material (e.g., in the presence or absence of a stimulus). The optical energy may be transferred to the fluorescent material, for example, via FRET. The fluorescent material 1202 may emit the absorbed optical energy and a second wavelength (hv₂). The first wavelength may be different than the second wavelength. The first wavelength may be shorter (i.e., higher energy) than the second wavelength.

Transfer efficiency of optical energy from the phosphorescent material 1201 to the fluorescent material 1202 may be a function of the distance between the phosphorescent material and the fluorescent material. For example, the transfer efficiency may be:

$$E = \frac{1}{1 + {( \frac{r}{{R}_{0}} )}^{6}}$$

where E is the optical energy transfer efficiency, r is the distance between a donor (e.g., the phosphorescent material) and an acceptor (e.g., the fluorescent material), and R₀ is the Förster radius of the donor/acceptor pair.

In some aspects, the transfer efficiency of the optical energy from the phosphorescent material to the fluorescent material may be a function of spectral overlap between an emission spectrum of the phosphorescent material and an absorption spectrum of the fluorescent material. For example, the Forster radius (R₀) may depend on the spectral overlap, as shown by:

$${R}_{0}^{6} = \frac{2.07 {κ}^{2} {Q}_{D}}{128 {π}^{5} {N}_{A} {n}^{4}} J$$

where R₀ is the distance at which energy is transferred with 50% efficiency, κ² is dipole orientation factor, Q_{D} is a quantum yield of the donor, N_{A} is Avogadro's number, n⁴ is the refractive index of the medium, and J is the spectral overlap of the donor and the acceptor (e.g., the spectral overlap between the emission spectrum of the phosphorescent material and the absorption spectrum of the fluorescent material.

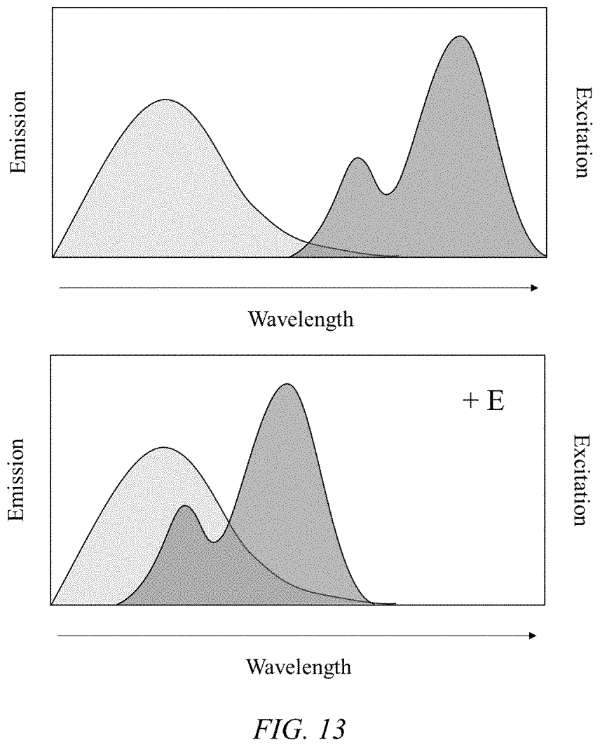

In some aspects, the spectral overlap between the emission spectrum of the phosphorescent material 1201 and the absorption spectrum of the fluorescent material 1202 may change in response to a stimulus. For example, the excitation spectrum of the fluorescent material may increase in energy or decrease in energy upon application of an electric or magnetic field, or to an applied voltage, thereby decreasing or increasing the spectral overlap of the emission spectrum of the phosphorescent material and the absorption spectrum of the fluorescent material, respectively. Accordingly, some batteries comprise a capacitor, electromagnet, pyroelectric material, ferroelectric material, or other mechanisms for generating an electric or magnetic field in a controlled manner. In such cases, the battery may also comprise a CPU or computational controller that adjusts a level of stimulus (e.g., electric field) in response to the level of ambient light or the charge state of the battery. For example, a battery may comprise a photometer disposed next to the optical charging layer. Since the light emission intensity from the optical charging layer can be proportional to the proportion of excited phosphors, the photometer may be able to detect when the optical charging layer is close to saturation (e.g., at least 80% of phosphors are in an excited state) and turn on an electric or magnetic field to affect discharge from the optical charging layer. FIG. 13 illustrates an exemplary change in spectral overlap in response to an applied electric field. In some aspects, the change in the excitation spectrum of the fluorescent material in response to an applied electric field may be a quantum confined Stark effect, approximated by:

$$Δ E \approx - 24 {( \frac{2}{3 π} )}^{6} \frac{{e}^{2} {F}^{2} {m}_{t o t}^{*} {L}^{4}}{{ℏ}^{2}}$$

where ΔE is the change in band separation of excited states of the acceptor (e.g., the fluorescent material), F is the strength of the electric field, m*ₜₒₜ is the sum of the electron effective mass and the hole effective mass, and L is the width of the energy well. In some instances, the stimulus may be a change in pressure, a change in thermal energy, or a change in Fermi level, or a combination thereof. For example, the excitation spectrum of the fluorescent material may increase in energy or decrease in energy upon application of a pressure. Alternatively or in addition, the excitation spectrum of the fluorescent material may increase in energy or decrease in energy upon application of thermal energy, e.g., an increase in temperature. The stimulus may also affect the emission spectrum of a phosphorescent material, e.g., by red shifting its emission spectrum, and thereby potentially altering its energy transfer efficiency to a fluorophore acceptor.

A stimulus may also affect the light emission rate of a phosphorescent material. Application of a stimulus may lower a phosphorescence lifetime (e.g., of a phosphor embedded in a wafer) by 1, 2, 3, 4, 5 or more orders of magnitude. For example, an electric field or applied voltage may lower a phosphorescence lifetime from 6 hours to 2 seconds (roughly 5 orders of magnitude), allowing for tight control of emission rate and timing. For example, the phosphorescence lifetime may be controlled to the order of days, hours, minutes, or seconds. Such control may optimize the efficiency of the photovoltaic cell, which may reach saturation current at a relatively low photon flux. Therefore, optimal phosphorescence discharge times may be on the order of 10's or 100's of seconds.

In particular cases, a phosphor in the optical charging layer is oriented with respect to a switchable electric or magnetic field so as to maximize the corresponding Stark or Zeeman effect. For example, the optical charging layer may comprise a crystal with phosphor dopants that occupy specific lattice sites, thereby collectively orienting the phosphors, and allowing placement of the field-inducing device at an optimal orientation (e.g., the orientation that induces the desired phosphorescent lifetime). Stimulus application may provide regional control over emission. A device may be configured to apply complex or separate stimuli to multiple portions of the optical layer, thereby allowing area- and time-specific discharge. For example, an optical layer may be disposed next to a chip comprising a 20×20 array of ferroelectric materials, allowing the chip to control phosphorescence from 400 distinct regions of the optical layer and control the regions in which light is emitted, thereby configuring the device for image projection. A battery may be configured to emit a number of pixels. The emission may be internal (e.g., on an interior surface of the battery, such as a photovoltaic cell) or external (i.e., projecting away from the battery). The emission may comprise at least 40, at least 60, at least 80, at least 100, at least 150, at least 200, at least 300, at least 400, at least 500, at least 600, at least 800, at least 1000, at least 1200, at least 1500, at least 2000, at least 2500, at least 3000, at least 3500, at least 4000, at least 5000, at least 8000, at least 12000, at least 15000, or at least 20000 pixels. A pixel may be at least 1 nm wide, 2 nm wide, 3 nm wide, 4 nm wide, 5 nm wide, 6 nm wide, 8 nm wide, 10 nm wide, 15 nm wide, 20 nm wide, 25 nm wide, 30 nm wide, 40 nm wide, 50 nm wide, 60 nm wide, 80 nm wide, 100 nm wide, 120 nm wide, 150 nm wide, 200 nm wide, 250 nm wide, 500 nm wide, 1 micron wide, or more.

Phosphorescence lifetime may also be modulated by temperature. A device may comprise a phosphor that exhibits a temperature dependent light emission rate. A battery may comprise an internal temperature control mechanism, or may be coupled to a temperature control device. Such a battery may impart faster light emission rates by raising the temperature of the optical charging layer and lower the light emission rate by lowering the temperature of the optical charging layer. A battery may perform automated temperature control based upon its charge state or on the level of ambient light.

The fluorescent material and the phosphorescent material may be arranged in an optical charging layer of a photon battery assembly, for example as shown in FIG. 12B. A photon battery assembly 1210 may comprise a light source 1211, an optical charging layer 1212, and a photovoltaic cell 1213. The light source, the optical charging layer, and the photovoltaic cell may be arranged in any configuration described herein. Regardless of contact between the optical charging layer and the light source, the optical charging layer and the light source may be in optical communication. For example, as described elsewhere herein, the optical charging layer and the light source may be in optical communication via a waveguide. Regardless of contact between the optical charging layer and photovoltaic cell, the optical charging layer and the photovoltaic cell may be in optical communication. For example, as described elsewhere herein, the optical charging layer and the photovoltaic cell may be in optical communication via a waveguide. The fluorescent material and the phosphorescent material may be arranged such that the phosphorescent material is in optical communication with the light source 1211 and the fluorescent material is in optical communication with the photovoltaic cell 1213. The optical charging layer 1212 can be crystalline, solid, liquid, ceramic, in powder form, granular or other particle form, liquid form, or in any other shape, state, or form. The optical charging layer may comprise a plurality of grains or particles of phosphorescent material. The optical charging layer also may comprise a thin film or wafer. The thin film or wafer may comprise a diameter of at least 2 cm, 3 cm, 4 cm, 5 cm, 8 cm, 10 cm, 12 cm, 15 cm, 20 cm, 25 cm, 30 cm, 50 cm, 80 cm, 100 cm, or 120 cm. The thin film or wafer may comprise a thickness of no more than 200 nm, 300 nm, 400 nm, 500 nm, 800 nm, or 1000 nm. The thin film or wafer may comprise a thickness of no more than 1 μm (1000 nm), 2 μm, 3 μm, 5 μm, 8 μm, 10 μm, 15 μm, 25 μm, 40 μm, 50 μm, 80 μm, or 100 μm. The thin film or wafer may comprise a thickness of at least 100 μm, 200 μm, 300 μm, 400 μm, 500 μm, 800 μm, 1 mm (1000 μm), 1.2 mm, 1.5 mm, 2 mm, or 2.5 mm. The thin film or wafer may comprise a surface feature such as a ridge, groove, well, trench, bump, or protrusion (e.g., a rod shaped protrusion). The surface feature may separate a phosphor from a fluorophore. For example, a wafer may comprise a phosphorescent material at the bottom of a trench and a fluorescent material at the top of a trench. A phosphorescent material may be embedded within a wafer or thin film. A fluorescent material may be embedded within a wafer or thin film. A phosphorescent material may be coated on a portion of a wafer or thin film. A fluorescent material may be coated on a portion of a wafer or thin film. A thin film or wafer may comprise a millimeter or hundreds of micrometer thick semiconductor, and may comprise a crystalline material such as strontium aluminate. Use of a wafer for an optical charging layer may allow for standard semiconductor processing, such as photolithography, MOCVD, CVD, ALD, sputtering, ion implantation, diffusion and laser or standard annealing. A wafer or thin film may comprise a II-VI semiconductor such as ZnS or CdTe, a III-V semiconductor such as GaAs, a silicon semiconductor, a germanium semiconductor, an aluminate such as strontium aluminate, as well as other host matrix materials for phosphorescent crystals. A thin film or wafer may comprise a quantum dot, nanorod, quantum well, or other phosphorescent or fluorescent nanomaterial. One or more grain or particle of phosphorescent material of the plurality of grains or particles of phosphorescent material may be surrounded by or coated with one or more particles of fluorescent material, as illustrated in FIG. 12A. The phosphorescent material may absorb optical energy from the light source at a first wavelength. In the presence or absence of a stimulus (e.g., in the absence of an applied electric field), the phosphorescent material may store the optical energy, as described elsewhere herein. In some aspects, the phosphorescent material may store the optical energy for at least about 1 hr, 2 hr, 3 hr, 4 hr, 5 hr, 6 hr, 7 hr, 8 hr, 9 hr, 10 hr, 11 hr, 12 hr, 1 day, 2 days, 3 days, 4 days, 1 week, 2 weeks, 3 weeks, or longer. Upon a change in the stimulus (e.g., application of an electric field), the optical energy may be transferred from the phosphorescent material to the fluorescent material. In some aspects, the optical energy may be transferred via FRET, RET, or Dexter transfer, as described elsewhere herein. The fluorescent material may then emit the optical energy at a second wavelength. In some aspects, the second wavelength may be different than the first wavelength. The second wavelength may be longer than the first wavelength. The optical energy emitted by the fluorescent material may be absorbed by the photovoltaic cell 1213, as described elsewhere herein. The configuration of the photon battery assembly with the phosphorescent material and the fluorescent material is not limited to FIG. 12B. For example, the photon battery may be arranged as shown in any one of FIG. 1-FIG. 9.

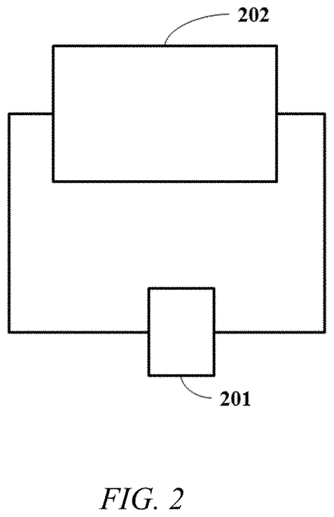

FIG. 2 shows a photon battery in communication with an electrical load. The photon battery 201 can power an electrical load 202. The photon battery and the electrical load can be in electric communication, such as via an electric circuit. While FIG. 2 shows a circuit, the circuit configuration is not limited to the one shown in FIG. 2. The electrical load can be an electrical power consuming device. The electrical load can be an electronic device, such as a personal computer (e.g., portable PC), slate or tablet PC (e.g., Apple® iPad, Samsung® Galaxy Tab), telephone, Smart phone (e.g., Apple® iPhone, Android-enabled device, Blackberry®), or personal digital assistant. The electronic device can be mobile or non-mobile. The electrical load can be a vehicle, such as an automobile, electric car, train, boat, or airplane. The electrical load can be a power grid. In some cases, the electrical load can be another battery or other energy storage system which is charged by the photon battery. In some instances, the photon battery can be integrated in the electrical load. In some instances, the photon battery can be permanently or detachably coupled to the electrical load. For example, the photon battery can be removable from the electrical load.

In some cases, a photon battery 201 can power a plurality of electrical loads in series or in parallel. In some cases, a photon battery can power a plurality of electrical loads simultaneously. For example, the photon battery can power 2, 3, 4, 5, 6, 7, 8, 9, 10 or more electrical loads simultaneously. In some cases, a plurality of photon batteries, electrically connected in series or in parallel, can power an electrical load. In some cases, a combination of one or more photon batteries and one or more other types of energy storage systems (e.g., lithium ion battery, fuel cell, etc.) can power one or more electrical loads.

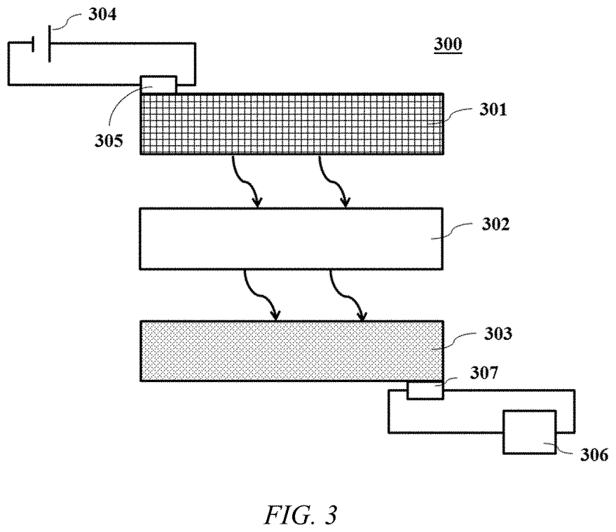

FIG. 3 shows an exemplary photon battery assembly in application. Any and all circuits illustrated in FIG. 3 are not limited to such circuitry configurations. A photon battery assembly 300 can be charged by a power source 304 and discharge power to an electrical load 306. The photon battery assembly can comprise a light source 301, such as a LED or a set of LEDs. The light source can be in electrical communication with the power source 304 through a port 305 of the light source. For example, the power source and the port 305 can be electrically connected via a circuit. The power source 304 may be external or internal to the photon battery assembly 300. The power source can be a power supplying device, such as another energy storage system (e.g., another photon battery, lithium ion battery, supercapacitor, fuel cell, etc.). The power source can be an electrical grid.

The light source 301 can receive electrical energy and emit optical energy at a first wavelength, such as via a light-emitting surface of the light source. The light-emitting surface can be adjacent to an optical charging layer 302. The light source can be in optical communication with the optical charging layer. The optical charging layer can be configured to absorb optical energy at the first wavelength and, content on the presence or absence of a stimulus, emit optical energy at a second wavelength or store optical energy for later emission. In some cases, the rate of emission of the optical energy at the second wavelength can be slower than the rate of absorption of the optical energy at the first wavelength. In some cases, the rate of emission is dependent on a stimulus, for example an applied electric field. An advantage of this stimulus-dependent energy storage or emission is that energy may be stored or released on-demand. In some instances, the phosphorescent material can store and/or discharge energy for at least about 1 hr, 2 hr, 3 hr, 4 hr, 5 hr, 6 hr, 7 hr, 8 hr, 9 hr, 10 hr, 11 hr, 12 hr, 1 day, 2 days, 3 days, 4 days, 1 week, 2 weeks, 3 weeks, or longer.

The optical energy may be transferred from the phosphorescent material to a fluorescent material. In some instances, the optical energy transfer increases or decreases in response to a stimulus, for example, an applied electric field. In an example, an optical energy transfer efficiency increases when an electric field is applied and decreases when the electric field is removed. In some instances, optical energy may be stored in the phosphorescent material when the optical energy transfer efficiency is low. The stimulus may be applied or removed, thereby alternating between storing the optical energy and transferring the optical energy. In this way, the photon battery assembly may be configured to store or release energy on-demand in response to a stimulus.

The photon battery assembly can comprise a photovoltaic cell 303. The photovoltaic cell can be configured to absorb optical energy at the second wavelength, such as via a light-absorbing surface of the photovoltaic cell. The photovoltaic cell can be in optical communication with the optical charging layer 302. The light-absorbing surface of the photovoltaic cell can be adjacent to the optical charging layer. The photovoltaic cell can generate electrical power from the optical energy absorbed. The electrical power generated by the photovoltaic cell can be used to power an electrical load 306. The photovoltaic cell can be in electrical communication with the electrical load through a port 307 of the photovoltaic cell. For example, the electrical load and the port 307 can be electrically connected via a circuit.

The energy stored by the photon battery assembly 300 can be charged and/or recharged multiple times. The power generated by the photon battery assembly can be consumed multiple times. The photon battery assembly can be charged and/or recharged by supplying electrical energy (or power) to the light source 301, such as through the port 305. The photon battery assembly 300 can discharge power by directing electrical power generated by the photovoltaic cell to the electrical load 306, such as through the port 307. For example, the photon battery assembly 300 can last (e.g., function for) at least 1, 2, 3, 4, 5, 6, 7, 8, 9, 10, 100, 500, 1000, 10⁴, 10⁵, 10⁶, or more recharge (or consumption) cycles.

The photon battery assembly 300 may provide superior charging rates to those of conventional chemical batteries, for example, on the order of 2, 3, 4, 5, 6, 7, 8, 9, 10, 20, 30, 40, 50, 60, 70, 80, 90, 100 times faster or more. For example, the photon battery assembly can charge at a speed of at least about 800 watts per cubic centimeters (W/cc), 850 W/cc, 900 W/cc, 1000 W/cc, 1050 W/cc, 1100 W/cc, 1150 W/cc, 1200 W/cc, 1250 W/cc, 1300 W/cc, 1350 W/cc, 1400 W/cc, 1450 W/cc, 1500 W/cc or greater. Alternatively, the photon battery assembly can charge at a speed of less than about 800 W/cc. The photon battery assembly may provide superior lifetimes to those of conventional chemical batteries, for example, on the order of 2, 3, 4, 5, 6, 7, 8, 9, 10 times more recharge cycles or more.

The photon battery assembly 300 may be stable and function effectively in relatively cold operating temperature conditions. For example, the photon battery assembly may function stably in operating temperatures as low as about −55° Celsius (° C.) and as high as about 65° C. The photon battery assembly may function stably in operating temperatures lower than about −55° C. and higher than about 65° C. In some instances, the photon battery assembly may function stably under any operating temperatures for which the light source (e.g., LEDs) functions stably. The photon battery assembly may not generate excess operating heat.

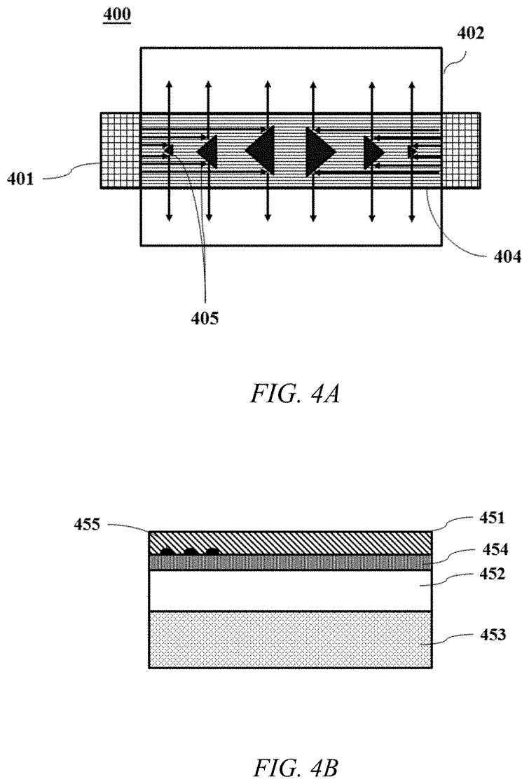

FIG. 4A illustrates a photon battery assembly with a waveguide. A photon battery assembly 400 can comprise a light source 401, an optical charging layer 402, a photovoltaic cell (not shown), and a waveguide 404. The waveguide may be adjacent to the light source and the optical charging layer. For example, the waveguide may be sandwiched by the light source and the optical charging layer. In other examples, as shown in FIG. 4A, some surfaces of the waveguide may be adjacent to the optical charging layer and some surfaces of the waveguide may be adjacent to the light source. In some instances, additionally, the waveguide may be adjacent to the photovoltaic cell. The configuration of the photon battery assembly with the waveguide is not limited to FIG. 4A.

Regardless of contact between the optical charging layer 402 and waveguide 404, the optical charging layer and the waveguide may be in optical communication. Regardless of contact between the light source 401 and waveguide, the light source and the waveguide may be in optical communication. In some instances, regardless of contact between the photovoltaic cell and waveguide, the photovoltaic cell and the waveguide may be in optical communication.

The waveguide 404 may or may not be contacting the light source 401. If the waveguide and the light source are in contact, the waveguide can interface a light-emitting surface of the light source. The waveguide and the light source can be coupled or fastened together at the interface, such as via a fastening mechanism. In some instances, a support carrying the light source and/or a support carrying the waveguide may be coupled or fastened together at the interface. Examples of fastening mechanisms may include, but are not limited to, form-fitting pairs, hooks and loops, latches, staples, clips, clamps, prongs, rings, brads, rubber bands, rivets, grommets, pins, ties, snaps, velcro, adhesives, tapes, a combination thereof, or any other types of fastening mechanisms. In some instances, the waveguide may have adhesive and/or cohesive properties and adhere to the light source without an independent fastening mechanism. The waveguide and the light source can be permanently or detachably fastened together. For example, the waveguide and the light source can be disassembled from and reassembled into the photon battery assembly 400 without damage (or with minimal damage) to waveguide and/or the light source. Alternatively, while in contact, the waveguide and the light source may not be fastened together.

If the waveguide 404 and the light source 401 are not in contact, the waveguide can otherwise be in optical communication with a light-emitting surface of the light source. For example, the waveguide can be positioned in an optical path of light emitted by the light-emitting surface of the light source. In some instances, there can be an air gap between the waveguide and the light source. In some instances, there can be another intermediary layer, such as a solid material (e.g., glass, plastic, etc.) and/or another waveguide, between the waveguide and the light source. The intermediary layer can be air and/or other fluid. The intermediary layer can be a light guide or another layer of optical elements (e.g., lens, reflector, diffusor, beam splitter, etc.). In some instances, there can be a plurality of intermediary layers between the waveguide and the light source. In some instances, the waveguide may be in optical communication with one or more surfaces of the waveguide. For example, the light source may comprise an array and/or row of LEDs that are in optical communication with one or more surfaces of the waveguide. The waveguide may receive light from the light source from any surface. In some instances, a surface of the waveguide in optical communication with a surface of a light source may be parallel, perpendicular, or at any angle whether in direct contact or not in contact. Either or both surfaces may be flat. Either or both surfaces may be angled and/or have a curvature (e.g., convex, concave). Either or both surfaces may have any surface profile.

The waveguide 404 may or may not be contacting the optical charging layer 402. If the waveguide and the optical charging layer are in contact, the waveguide can interface a light-absorbing surface of the optical charging layer. The waveguide and the optical charging layer can be coupled or fastened together at the interface, such as via a fastening mechanism. In some instances, a support carrying the optical charging layer and/or a support carrying the waveguide may be coupled or fastened together at the interface. Examples of fastening mechanisms may include, but are not limited to, form-fitting pairs, hooks and loops, latches, staples, clips, clamps, prongs, rings, brads, rubber bands, rivets, grommets, pins, ties, snaps, velcro, adhesives, tapes, a combination thereof, or any other types of fastening mechanisms. In some instances, the waveguide may have adhesive and/or cohesive properties and adhere to the optical charging layer without an independent fastening mechanism. In some instances, the optical charging layer may have adhesive and/or cohesive properties and adhere to the waveguide without an independent fastening mechanism. For example, the optical charging layer may be painted or coated on a light-emitting surface of the waveguide. The waveguide and the optical charging layer can be permanently or detachably fastened together. For example, the waveguide and the optical charging layer can be disassembled from and reassembled into the photon battery assembly 400 without damage (or with minimal damage) to waveguide and/or the optical charging layer. Alternatively, while in contact, the waveguide and the optical charging layer may not be fastened together.

If the waveguide 404 and the optical charging layer 402 are not in contact, the waveguide can otherwise be in optical communication with a light-absorbing surface of the optical charging layer. For example, the optical charging layer can be positioned in an optical path of light emitted by the light-emitting surface of the waveguide. In some instances, there can be an air gap between the waveguide and the optical charging layer. In some instances, there can be another intermediary layer, such as another waveguide, between the waveguide and the optical charging layer. The intermediary layer can be air or other fluid. The intermediary layer can be a light guide or another layer of optical elements (e.g., lens, reflector, diffusor, beam splitter, etc.). In some instances, there can be a plurality of intermediary layers between the waveguide and the optical charging layer. In some instances, the waveguide may be in optical communication with one or more surfaces of the optical charging layer. The optical charging layer may receive light from the waveguide from any surface. In some instances, a surface of the waveguide in optical communication with a surface of a optical charging layer may be parallel, perpendicular, or at any angle, whether in direct contact or not in contact. Either or both surfaces may be flat. Either or both surfaces may be angled and/or have a curvature (e.g., convex, concave). Either or both surfaces may have any surface profile.

The waveguide 404 may be configured to direct waves at a first wavelength emitted from the light source 401 to the optical charging layer 402. Beneficially, the waveguide may deliver optical energy from the light source to the optical charging layer with great efficiency and minimal loss of optical energy (or other forms of energy). The waveguide may provide optical communication between the light source and distributed volumes of the optical charging layer where otherwise some volumes of optical charging layer would not be in optical communication with the light source, allowing for flexible arrangements of the light source relative to the optical charging layer. For example, without waveguides, the optical energy at the first wavelength emitted from the light source may be absorbed most efficiently by the immediately adjacent volume of optical charging layer (relative to the light source or otherwise in immediate optical communication with the light source), such as at the optical charging layer-light source interface. However, once such immediately adjacent optical charging layer absorbs the optical energy at the first wavelength, it may no longer have capacity to receive further optical energy and/or prevent other volumes of optical charging layer (further downstream in the optical path) from absorbing such optical energy. While large surface area interface between the optical charging layer and the light source may facilitate efficient optical energy delivery from the light source to the optical charging layer, this may be impractical when constructing compact energy storage systems. By implementing waveguides to facilitate optical communication between the light source and the optical charging layer, different volumes of the optical charging layer may evenly absorb the optical energy from the light source even if such optical charging layer and the light source are not immediately adjacent.

The waveguide 404 may have a maximum dimension (e.g., width, length, height, radius, diameter, etc.) of at least about 10 micrometers, 20 micrometers, 30 micrometers, 40 micrometers, 50 micrometers, 60 micrometers, 70 micrometers, 80 micrometers, 90 micrometers, 100 micrometers, 200 micrometers, 300 micrometers, 400 micrometers, 500 micrometers, 600 micrometers, 700 micrometers, 800 micrometers, 900 micrometers, 1 millimeter (mm), 2 mm, 3 mm, 4 mm, 5 mm, 6 mm, 7 mm, 8 mm, 9 mm, 1 centimeter (cm), 2 cm, 3 cm, 4 cm, 5 cm, 10 cm, 15 cm, 20 cm, 30 cm, 40 cm, 50 cm or more. Alternatively or in addition, the waveguide may have a maximum dimension of at most about 50 cm, 40 cm, 30 cm, 20 cm, 15 cm, 10 cm, 5 cm, 4 cm, 3 cm, 2 cm, 1 cm, 9 mm, 8 mm, 7 mm, 6 mm, 5 mm, 4 mm, 3 mm, 2 mm, 1 mm, 900 micrometers, 800 micrometers, 700 micrometers, 600 micrometers, 500 micrometers, 400 micrometers, 300 micrometers, 200 micrometers, 100 micrometers, 90 micrometers, 80 micrometers, 70 micrometers, 60 micrometers, 50 micrometers, 40 micrometers, 30 micrometers, 20 micrometers, 10 micrometers, or less. The waveguide may be square, rectangular (e.g., having an aspect ratio for length to width of about 1:1.1, 1:1.2, 1:1.3, 1:1.4, 1:1.5, 1:1.6, 1:1.7, 1:1.8, 1:1.9, 1:2, 1:3, 1:4, 1:5, 1:10, etc.), or any other shape. The waveguide may comprise material such as plastic or glass. The waveguide may comprise material used in an injection mold.

For example, in FIG. 4A, the optical energy emitted from the light source 401 is directed through the layer of waveguide 404 to reach various locations of the phosphorescent material 402. As described elsewhere herein, after a time delay, the optical charging layer 402 may emit optical energy at the second wavelength for absorption by a photovoltaic cell (not shown). The waveguide may comprise one or more reflective surfaces 405 to direct waves from the light source to the optical charging layer. The one or more reflective surfaces may have increasingly large reflective surfaces in the optical path within the waveguide to allow some waves to be reflected at a first reflective surface for excitation of a first volume of optical charging layer, and some waves to travel further before being reflected at a second reflective surface for excitation of a second volume of optical charging layer that is further from the light source than the first volume, and some waves to travel further before being reflected at a third reflective surface for excitation of a third volume of optical charging layer that is further than the second volume, and so on. There may be any number of reflective surfaces in the waveguide. For example, there may be at least about 3, 4, 5, 6, 7, 8, 9, 10, 20, 30, 40, 50, 60, 70, 80, 90, 100, 200, 300, 400, 500, or more reflective surfaces. Alternatively or in addition, a single reflective surface may gradually increase surface area, such as in a conical shape, in the optical path within the waveguide to achieve a similar outcome.

In some instances, the waveguide may be adjacent to the optical charging layer from a first surface, and adjacent to the light source from a second surface, wherein the first surface and the second surface are substantially orthogonal. The one or more reflective surfaces may be configured to direct waves in a substantially orthogonal direction such as to receive from the light source from the second surface and to transmit through the first surface. Alternatively or in addition, the first surface and the second surface may be at any other angle and the one or more reflective surfaces may be configured to direct waves in the other angle, such as to receive from the light source from the second surface and to transmit through the first surface. As illustrated in FIG. 4A, the waveguide may be adjacent to a plurality of optical charging layers (e.g., interfacing different surfaces of the waveguide). The one or more reflective surfaces may be configured to direct waves received from the light source to the plurality of optical charging layers by reflecting the waves (e.g., light) to the plurality of layers.

In some instances, alternative to or in addition to the light source 401, the photon battery assembly 400 may be charged (or the optical charging layer excited) wirelessly. In some embodiments, a photon battery assembly can comprise the optical charging layer 402, a photovoltaic cell (not shown), and the waveguide 404, without having the light source 401 integrated in the assembly. For example, the light source 401 (illustrated in FIG. 4A) can be remote and detached from the other components. The light source may be driven by a power source that is separate and/or detached from the photon battery assembly that it charges. Such remote light source can be configured to provide optical energy to the assembly to achieve wireless charging of the assembly. Regardless of where the light source 401 is disposed with respect to the assembly and/or the waveguide, the light source may be in optical communication with the waveguide and/or the optical charging layer to provide optical energy for excitation of the phosphorescent material. The remote light source can be configured to provide optical energy at a higher energy level than the optical energy emitted by the phosphorescent material or the fluorescent material. For example, where the phosphorescent material is strontium aluminate, the remote light source may provide optical energy at wavelengths that is shorter than the emission wavelength of about 520 nanometers. For example, the remote light source may provide waves at wavelengths between about 300 nanometers to about 470 nanometers. The remote light source may provide such optical energy via LED, lasers, or other optical beams, as described elsewhere herein. In some instances, a photon battery assembly configuration may maximize (or otherwise) increase the exposed surface area of one or more waveguides and/or the phosphorescent material to facilitate such wireless charging. Beneficially, the compactness and the transportability of the photon battery assemblies described herein may be greatly increased by allowing for wireless charging. Further, such wireless charging may allow for fast charging, optical charging, and on-demand charging, as well as benefit from the general widespread availability of charging sources (e.g., availability of light sources). Any of the photon battery assemblies may be configured for wireless charging, either in addition to wired (e.g., integrated) light source charging, or alternative to integrated light source charging.

In some instances, the waveguide may be coated at one or more surfaces. Otherwise, the waveguide may be adjacent to and/or in contact with another layer at one or more surfaces. For example, the waveguide may be coated at one or more surfaces that interfaces the optical charging layer 402. An example coating configuration is shown in FIG. 4B. A photon battery assembly can comprise a light source (not shown), an optical charging layer 452, a photovoltaic cell 453, and a waveguide 451, which has a coating 454 on one or more of its surfaces that interfaces the phosphorescent material. The waveguide may be adjacent to the light source and the optical charging layer, as described elsewhere herein.

The coating 454 may be disposed between the waveguide 451 and the optical charging layer 452. In some instances, all surfaces of the waveguide interfacing (or in optical communication with) the optical charging layer may be covered by the coating. In other instances, a portion of the surfaces interfacing (or in optical communication with) the optical charging layer may be covered by the coating and a portion of the surfaces interfacing (or in optical communication with) the optical charging layer may not be covered by the coating. For example, such surfaces may be uncovered by anything and in direct optical communication with the optical charging layer, or be covered by another coating or another layer (e.g., glass, another waveguide, etc.) and be in optical communication with the optical charging layer through the other coating or other layer. In some instances, the other layer can be a light guide or another layer of optical elements (e.g., lens, reflector, diffusor, beam splitter, etc.). In some instances, there may be a plurality of layers between the waveguide 451 and the optical charging layer 452, including the coating 454. For example, the plurality of layers may include an air gap or other fluid gap, a solid layer (e.g., glass, plastic.), other optical elements (e.g., lens, reflector, diffusor, beam splitter, etc.), and/or any other layer, in any combination, and arranged in any order or sequence. Regardless of coating or waveguide configuration, the optical charging layer 452 and the waveguide 451 may be in optical communication.

The waveguide 404 may or may not be contacting the coating 454. The waveguide and the coating can be coupled or fastened together at the interface, such as via a fastening mechanism. In some instances, a support carrying the coating and/or a support carrying the waveguide may be coupled or fastened together at the interface. Examples of fastening mechanisms may include, but are not limited to, form-fitting pairs, hooks and loops, latches, staples, clips, clamps, prongs, rings, brads, rubber bands, rivets, grommets, pins, ties, snaps, velcro, adhesives, tapes, a combination thereof, or any other types of fastening mechanisms. In some instances, the coating may have adhesive and/or cohesive properties and adhere to the waveguide without an independent fastening mechanism. In some instances, the waveguide may have adhesive and/or cohesive properties and adhere to the coating without an independent fastening mechanism. For example, the coating may be painted or coated on a surface of the waveguide. The waveguide and the coating can be permanently or detachably fastened together. For example, the waveguide and the coating can be disassembled from and reassembled into the photon battery assembly without damage (or with minimal damage) to waveguide and/or the coating. Alternatively, while in contact, the waveguide and the coating may not be fastened together.

The coating 454 may be a dichroic coating or comprise other optical filter(s). For example, the coating may be configured to allow waves at certain first wavelength(s) (e.g., longer wavelength) in to excite the optical charging layer 452, but reflect the waves at certain second wavelength(s) (e.g., shorter wavelength). For example, waves with longer wavelength(s) may be allowed to reach the optical charging layer through the coating, and waves with shorter wavelengths(s) emitted by the optical charging layer may be reflected by the coating and kept within the optical charging layer to (i) increase the likelihood that such waves with shorter wavelengths are incident upon the photovoltaic cell 453, and (ii) prevent such waves from entering the waveguide 451 and generating undesired heat. The coating 454 may comprise antireflective properties, thereby increasing photon flux into the optical charging layer 452.

The coating 454 may have any thickness. For example, the coating may be between 0.5 micrometers and 5 micrometers. In some instances, the coating may be at least about 0.5, 0.6, 0.7, 0.8, 0.9, 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, 5.0 micrometers or more in thickness. Alternatively or in addition, the coating may be at most about 5.0, 4.9, 4.8, 4.7, 4.6, 4.5, 4.4, 4.3, 4.2, 4.1, 4.0, 3.9, 3.8, 3.7, 3.6, 3.5, 3.4, 3.3, 3.2, 3.1, 3.0, 2.9, 2.8, 2.7, 2.6, 2.5, 2.4, 2.3, 2.2, 2.1, 2.0, 1.9, 1.8, 1.7, 1.6, 1.5, 1.4, 1.3, 1.2, 1.1, 1.0, 0.9, 0.8, 0.7, 0.6, 0.5 micrometers or less in thickness.

The thickness of the optical charging layer 452 may be optimized to maximize energy storage and conversion. Many optical charging layer materials (e.g., dysprosium doped strontium aluminate) are highly transmissive over mm lengths, providing minimal absorption or dispersion aside from absorption by interspersed phosphors. In part due to this characteristic, light collection efficiency often increases with optical charging layer thickness. However, for many optical charging layer materials, increased thickness can also lead to reabsorption of phosphorescent emissions (e.g., by other phosphors within the material), thereby diminishing the efficiency with which absorbed light is converted by the photovoltaic cell. Often, the optical charging layer thickness balances these two effects, and lends to widths of at least about 10, 11, 12, 13, 14, 15, 16, 17, 18, 19, 20, 21, 22, 23, 24, 25, 26, 27, 28, 29, 30, 40, 50, 60, 70, 80, 90, 100, 120 micrometers or more. Alternatively, the optical charging layer may have a thickness of at most about 120, 100, 90, 80, 70, 60, 50, 40, 30, 29, 28, 27, 26, 25, 24, 23, 22, 21, 20, 19, 18, 17, 16, 15, 14, 13, 12, 11, 10 micrometers or less.

In some instances, an optical charging layer comprises a feature that enables it to have a greater thickness, such as a trench, groove, hole (e.g., empty space within the material), indentation, or ridge. The feature may be 1 to 5, 3 to 10, 5 to 15, 10 to 20, 20 to 40, 30 to 50, or 40 to 80, 50 to 100, 60 to 120, 80 to 140, 100 to 160, 120 to 180, or 150 to 250 microns thick or deep. When such a feature is present, the optical charging layer may be 10, 20, 30, 40, 50, 60, 70, 80, 90, 100, 110, 120, 150, 200, 250, or 300 microns thick, including the height of the feature.

Alternatively or in addition to the coating 454, the waveguide 451 may comprise a surface feature 455 (or multiple features) to facilitate the direction of waves towards a certain direction, and/or increase the uniformity of the direction in which waves are directed. For example, one or more surfaces of the waveguide may comprise physical structures or features, such as grooves, troughs, indentations, hills, pillars, walls, and/or other structures or features. In an example, a bottom surface of the waveguide may comprise one or more grooves formed inwards the waveguide such that waves from the light source are uniformly reflected in a direction towards the optical charging layer to excite the phosphorescent material. Such grooves (and/or other physical structures or features) may be patterned into the waveguide. The patterns may be regular or irregular. For example, the grooves may be spaced at regular intervals or irregularly spaced. In some instances, such grooves (and/or other physical structures or features) may be discrete features. The physical structure or feature may be formed by any mechanism, such as mechanical machining. In some instances, diamond turning can be used to etch or cut the physical structures or features (e.g., grooves) into the waveguide. In some instances, one or more physical features may be integral to the waveguide. In some instances, one or more physical features may be external to, and/or otherwise coupled/attached to the waveguide by any fastening mechanism described elsewhere herein. Alternatively or in addition to the coating 454 and/or the surface feature 455, the waveguide 451 may further comprise surface marking to facilitate the direction of waves towards a certain direction. For example, one or more surfaces of the waveguide may comprise painted markings having certain optical properties that facilitating the scattering of waves in a certain direction. For example, such painted markings may be white painted dots that facilitate scatter of light towards the optical charging layer to excite the phosphorescent material. The waveguide may comprise any number of such painted dots (or other surface markings). The waveguide may comprise any type of painted markings, including other colored dots. The markings may form a pattern. The patterns may be regular or irregular. For example, the dots may be spaced at regular intervals or irregularly spaced. In some instances, such dots may be discrete markings.

Any of the photon battery assemblies described herein may comprise a waveguide in optical communication with an optical filter, such as the dichroic coating described with respect to FIG. 4B, or comprise a waveguide comprising the physical features and/or markings described with respect to FIG. 4B. For example, the photon battery assembly 100 of FIG. 1 may comprise a waveguide (not shown) in optical communication with a coating disposed between the waveguide and the optical charging layer 102. For example, the photon battery assembly 400 of FIG. 4A may comprise a coating disposed between the waveguide 404 and the optical charging layer 402.

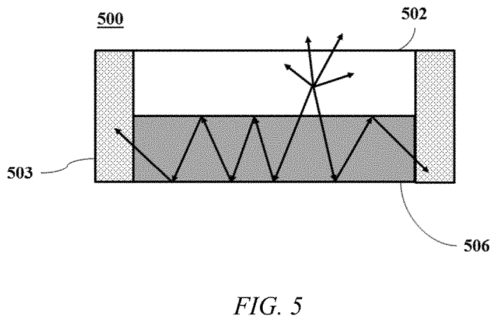

FIG. 5 illustrates another photon battery assembly with a waveguide. A photon battery assembly 500 can comprise a light source (not shown), an optical charging layer 502, a photovoltaic cell 503, and a waveguide 506. The waveguide may be adjacent to the photovoltaic cell and the optical charging layer. For example, the waveguide may be sandwiched by the photovoltaic cell and the optical charging layer. In other examples, as shown in FIG. 5, some surfaces of the waveguide may be adjacent to the optical charging layer and some surfaces of the waveguide may be adjacent to the photovoltaic cell. In some instances, additionally, the waveguide may be adjacent to the light source. The configuration of the photon battery assembly with the waveguide is not limited to FIG. 5.

Regardless of contact between the optical charging layer 502 and waveguide 506, the optical charging layer and the waveguide may be in optical communication. Regardless of contact between the photovoltaic cell 503 and waveguide, the photovoltaic cell and the waveguide may be in optical communication. In some instances, regardless of contact between the light source and waveguide, the light source and the waveguide may be in optical communication.

The waveguide 506 may or may not be contacting the photovoltaic cell 503. If the waveguide and the photovoltaic cell are in contact, the waveguide can interface a light-absorbing surface of the photovoltaic cell. The waveguide and the photovoltaic cell can be coupled or fastened together at the interface, such as via a fastening mechanism. In some instances, a support carrying the photovoltaic cell and/or a support carrying the waveguide may be coupled or fastened together at the interface. Examples of fastening mechanisms may include, but are not limited to, form-fitting pairs, hooks and loops, latches, staples, clips, clamps, prongs, rings, brads, rubber bands, rivets, grommets, pins, ties, snaps, velcro, adhesives, tapes, a combination thereof, or any other types of fastening mechanisms. In some instances, the waveguide may have adhesive and/or cohesive properties and adhere to the photovoltaic cell without an independent fastening mechanism. The waveguide and the photovoltaic cell can be permanently or detachably fastened together. For example, the waveguide and the photovoltaic cell can be disassembled from and reassembled into the photon battery assembly 500 without damage (or with minimal damage) to waveguide and/or the photovoltaic cell. Alternatively, while in contact, the waveguide and the photovoltaic cell may not be fastened together.

If the waveguide 506 and the photovoltaic cell 503 are not in contact, the waveguide can otherwise be in optical communication with a light-emitting surface of the photovoltaic cell. For example, the photovoltaic cell can be positioned in an optical path of light emitted by a light-emitting surface of the waveguide. In some instances, there can be an air gap between the waveguide and the photovoltaic cell. In some instances, there can be another intermediary layer, such as another waveguide, between the waveguide and the photovoltaic cell. The intermediary layer can be air or other fluid. The intermediary layer can be a light guide or another layer of optical elements (e.g., lens, reflector, diffusor, beam splitter, etc.). In some instances, there can be a plurality of intermediary layers between the waveguide and the photovoltaic cell.

The waveguide 506 may or may not be contacting the optical charging layer 502. If the waveguide and the optical charging layer are in contact, the waveguide can interface a light-emitting surface of the optical charging layer. The waveguide and the optical charging layer can be coupled or fastened together at the interface, such as via a fastening mechanism. In some instances, a support carrying the optical charging layer and/or a support carrying the waveguide may be coupled or fastened together at the interface. Examples of fastening mechanisms may include, but are not limited to, form-fitting pairs, hooks and loops, latches, staples, clips, clamps, prongs, rings, brads, rubber bands, rivets, grommets, pins, ties, snaps, velcro, adhesives, tapes, a combination thereof, or any other types of fastening mechanisms. In some instances, the waveguide may have adhesive and/or cohesive properties and adhere to the optical charging layer without an independent fastening mechanism. In some instances, the optical charging layer may have adhesive and/or cohesive properties and adhere to the waveguide without an independent fastening mechanism. For example, the optical charging layer may be painted or coated on the waveguide. The waveguide and the optical charging layer can be permanently or detachably fastened together. For example, the waveguide and the phosphorescent material can be disassembled from and reassembled into the photon battery assembly 500 without damage (or with minimal damage) to waveguide and/or the optical charging layer. Alternatively, while in contact, the waveguide and the optical charging layer may not be fastened together.

If the waveguide 506 and the optical charging layer 502 are not in contact, the waveguide can otherwise be in optical communication with a light-emitting surface of the optical charging layer. In some instances, there can be another intermediary layer, such as another waveguide, between the waveguide and the optical charging layer. The intermediary layer can be air or other fluid. The intermediary layer can be a light guide or another layer of optical elements (e.g., lens, reflector, diffusor, beam splitter, etc.). In some instances, there can be a plurality of intermediary layers between the waveguide and the optical charging layer.

The waveguide 506 may be configured to direct waves at a second wavelength emitted from the fluorescent material of the optical charging layer 502 to the photovoltaic cell 503. Beneficially, the waveguide may deliver optical energy from the optical charging layer to the photovoltaic cell with great efficiency and minimal loss of optical energy (or other forms of energy). The fluorescent material may emit optical energy at the second wavelength without directional specificity, such as in isotropic emission. The waveguide may provide optical communication between the photovoltaic cell and distributed volumes of the fluorescent material and the phosphorescent material where otherwise some volumes of fluorescent material and phosphorescent material would not be in optical communication with the photovoltaic cell, allowing for flexible arrangements of the photovoltaic cell relative to the phosphorescent material. For example, without waveguides, the optical energy at the second wavelength emitted from the fluorescent material of the optical charging layer may be absorbed most efficiently by the immediately adjacent light absorbing surface of the photovoltaic cell, if it reaches the photovoltaic cell at all. The optical energy that is emitted away from the light absorbing surface of the photovoltaic cell may be lost in the process. While large surface area interface between the optical charging layer and the photovoltaic cell may facilitate efficient optical energy delivery from the optical charging layer to the photovoltaic cell, this may be impractical and expensive when constructing compact energy storage systems. By implementing waveguides to facilitate optical communication between the photovoltaic cell and the optical charging layer, the photovoltaic cell may efficiently absorb the optical energy from the optical charging layer even if they are not immediately adjacent.

The waveguide 506 may have a maximum dimension (e.g., width, length, height, radius, diameter, etc.) of at least about 1 millimeter (mm), 2 mm, 3 mm, 4 mm, 5 mm, 6 mm, 7 mm, 8 mm, 9 mm, 1 centimeter (cm), 2 cm, 3 cm, 4 cm, 5 cm, 10 cm, 15 cm, 20 cm, 30 cm, 40 cm, 50 cm or more. Alternatively or in addition, the waveguide may have a maximum dimension of at most about 50 cm, 40 cm, 30 cm, 20 cm, 15 cm, 10 cm, 5 cm, 4 cm, 3 cm, 2 cm, 1 cm, 9 mm, 8 mm, 7 mm, 6 mm, 5 mm, 4 mm, 3 mm, 2 mm, 1 mm or less. The waveguide may be square, rectangular (e.g., having an aspect ratio for length to width of about 1:1.1, 1:1.2, 1:1.3, 1:1.4, 1:1.5, 1:1.6, 1:1.7, 1:1.8, 1:1.9, 1:2, 1:3, 1:4, 1:5, 1:10, etc.), or any other shape. The waveguide may comprise material such as plastic or glass. The waveguide may comprise material used in an injection mold.

For example, in FIG. 5, the optical energy emitted from the phosphorescent material 502 is directed through the layer of waveguide 506 to reach the photovoltaic cell 503. As described elsewhere herein, the phosphorescent material of the optical charging layer 502 may have absorbed optical energy at the first wavelength from a light source (not shown), such as in the configuration illustrated in FIG. 4A. The waveguide 506 may have a refractive index such as to allow for total internal reflection of the optical wave at the second wavelength within the waveguide 506 until such optical energy is transmitted to the photovoltaic cell 503. The waveguide may have a lower refractive index than any adjacent layer to the waveguide. In some instances, the waveguide may be adjacent to the optical charging layer from a first surface, and adjacent to the photovoltaic cell from a second surface, wherein the first surface and the second surface are substantially orthogonal. In some instances, the waveguide may be adjacent to a plurality of optical charging layers (e.g., interfacing different surfaces of the waveguide), and configured to direct waves received from the plurality of optical charging layers to the photovoltaic cell.

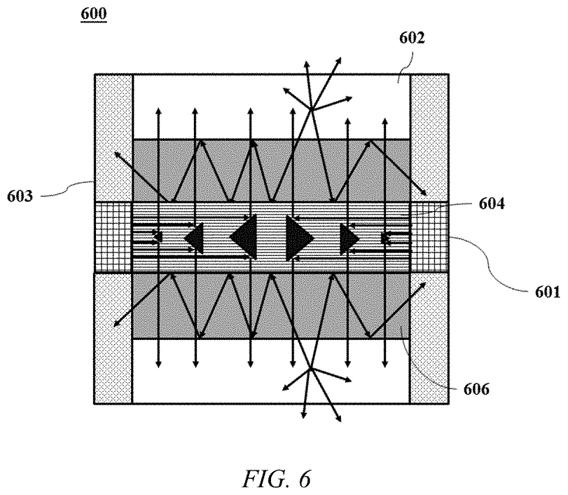

FIG. 6 illustrates another photon battery assembly with waveguides. A photon battery assembly 600 can comprise a light source 601, an optical charging layer 602, a photovoltaic cell 603, a first waveguide 604, and a second waveguide 606. In some instances, the first waveguide 604 may correspond to the waveguide 404 described with respect to FIG. 4. In some instances, the second waveguide 606 may correspond to the waveguide 506 described with respect to FIG. 5.

The photon battery assembly 600 may be constructed such that the first waveguide 604 is adjacent to the second waveguide 606, and the second waveguide is adjacent to the optical charging layer 602. The first waveguide and the optical charging layer may each be adjacent to two surfaces of the second waveguide that are substantially parallel. The first waveguide may be adjacent to the light source 601. The light source and the second waveguide may be adjacent to two surfaces of the first waveguide that are substantially orthogonal. The second waveguide may be adjacent to the photovoltaic cell 603. The photovoltaic cell and the optical charging layer may be adjacent to two surfaces of the second waveguide that are substantially orthogonal. In some instances, the photovoltaic cell and the light source may be substantially parallel and/or coplanar. The configuration of the photon battery assembly with waveguides is not limited to FIG. 6.

In operation, the photon battery may be charged via the first waveguide 604 which guides optical energy emitted by the light source 601 at the first wavelength to the optical charging layer 602. The optical energy received from the light source may be substantially orthogonally reflected (e.g., via a reflective surface) within the first waveguide to pass through the second waveguide 606 (with minimal energy loss) for even absorption across the phosphorescent material of the optical charging layer and subsequent excitation. After a time delay, or following application or removal of a stimulus, as described elsewhere herein, the phosphorescent material may transfer optical energy to the fluorescent material of the optical charging layer, and the fluorescent material may emit optical energy at a second wavelength. Such emission may be isotropic (e.g., non-direction specific). Such emission may also be anisotropic. A fluorophore may predominantly emit within a defined plane or axis. The emitted optical energy may be directed by the second waveguide, such as via total internal reflection, to the photovoltaic cell for absorption by the photovoltaic cell. Alternatively or in addition, the emitted optical energy may be directed to the photovoltaic cell directly. In some instances, the second waveguide may have a refractive index that is lower than that of the first waveguide and that of the phosphorescent material to allow for total internal reflection. As illustrated in FIG. 6, the photon battery may be stacked in a similar configuration.

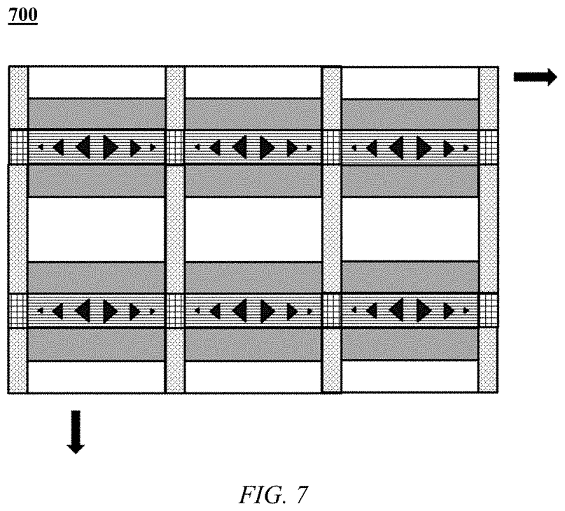

FIG. 7 shows a stack of a plurality of photon battery assemblies. A photon battery assembly can be connected to achieve different desired voltages, energy storage capacities, power densities, and/or other battery properties. For example, an energy storage system 700 may comprise a stack of a first photon battery assembly, a second photon battery assembly, a third photon battery assembly, a fourth photon battery assembly, and so on, which are stacked vertically or horizontally. Each photon battery assembly may comprise (or share) a light source, optical charging layer, photovoltaic cell, first waveguide, and second waveguide, as described elsewhere herein. While FIG. 7 shows six photon battery assemblies stacked together, any number of photon battery assemblies can be stacked together in any configuration. For example, at least 2, 3, 4, 5, 6, 7, 8, 9, 10, 15, 20, 25, 30, 35, 40, 45, 50, 100, 200, or more photon battery assemblies can be stacked together. While FIG. 7 shows a linear grid-like stack in the horizontal and vertical directions, the assemblies can be stacked in different configurations, such as in concentric (or circular) stacks.

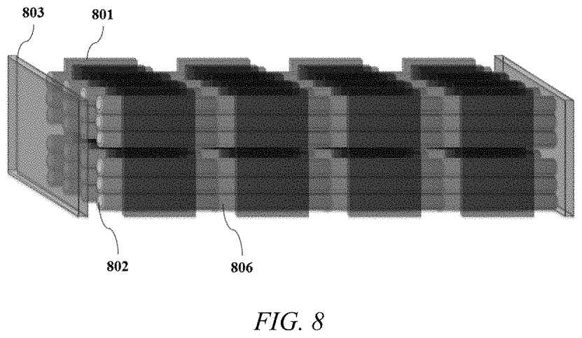

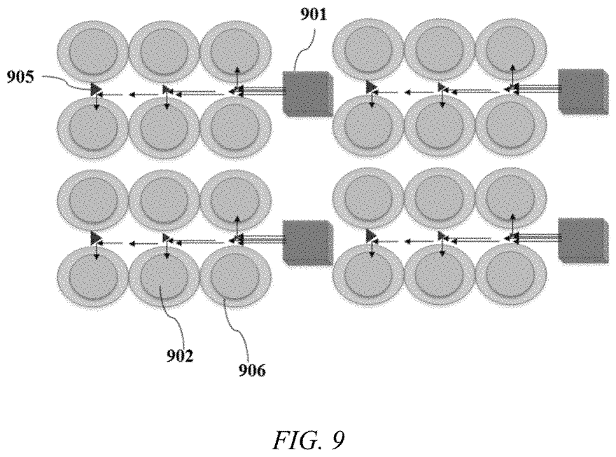

FIG. 8 shows an exploded view of another configuration for a photon battery assembly stack with hollow core waveguides. A waveguide 806 may comprise a hollow core. For example, the waveguide may be an optical fiber or cable with a hollow core. Alternatively, the waveguide may have a cavity or trench with an opening. The waveguide may have a plurality of cavities or trenches with a plurality of openings. The hollow core (or cavity or trench) may be filled by phosphorescent material 802 such as to form filled cylindrical units. Alternatively, the hollow core may be any shape (e.g., rectangular, triangular, hexagonal, non-polygonal, etc.). The cylindrical units may be linearly stacked, such as in groups of 2, 3, 4, 5, 6, 7, 8, 9, 10, 20, 30, 40, 50, 100, 200, or more units. The groups of linearly stacked cylindrical units may be sandwiched on opposing sides by light source panels 801. In some instances, a single light source panel may stretch along a length of a cylindrical unit. Alternatively, as shown in FIG. 8, a plurality of light source panels may be intermittently placed along the length of the single cylindrical unit. In some instances, groups of linearly stacked cylindrical units and the sandwiching light source panels may be stacked in alternating layers. Although this example shows four groups of six linearly stacked cylindrical units alternating with five light source panels for each unit length of cylindrical unit, the stack may be in any configuration (e.g., 25 groups of 7 linearly stacked cylindrical units alternating with 26 light source panels). A photovoltaic cell 803 may be adjacent to the end of the cylindrical units, substantially orthogonal to the lengths of the cylindrical units, and substantially orthogonal to the light source panels. The photon battery assembly may resemble a cuboid shape, as illustrated in FIG. 8. The photon battery assembly is not limited to the configuration illustrated in FIG. 8.

In some instances, the light source panel 801 may comprise a light source (e.g., LED) and a waveguide. The waveguide may correspond to the waveguide 404 described with respect to FIG. 4 and configured to direct optical energy from the light source to different cylindrical units. FIG. 9 illustrates a partial cross-sectional side view of the photon battery assembly stack of FIG. 8. The optical energy emitted by a light source 901 is directed by one or more reflective surfaces 905 in a first waveguide (e.g., in the light source panel 801) to the optical charging layer 902 in different cylindrical units. The optical energy may pass through a second waveguide 906 (configured to direct optical energy emitted from the optical charging layer to the photovoltaic cell (not shown)). The first waveguide may comprise increasingly larger reflective surfaces (e.g., 905) in the direction of the optical path of the optical energy emitted by the light source 901 such as to evenly distribute the optical energy to the different cylindrical units (e.g., in the linear stack).

Each photon battery assembly can be configured as described in FIG. 1-FIG. 9 or FIG. 12B. Alternatively, different components of the photon battery assembly (e.g., light source, optical charging layer, photovoltaic cell, first waveguide, second waveguide, coating, etc.) can be stacked in different configurations (e.g., orders). A plurality of photon battery assemblies can be electrically connected in series, in parallel, or a combination thereof. In some instances, there may be interconnects and/or other electrical components between each photon battery assembly. In some instances, a controller can be electrically coupled to one or more photon battery assemblies and be capable of managing the inflow and/or outflow of power from each or a combination of the battery assemblies.

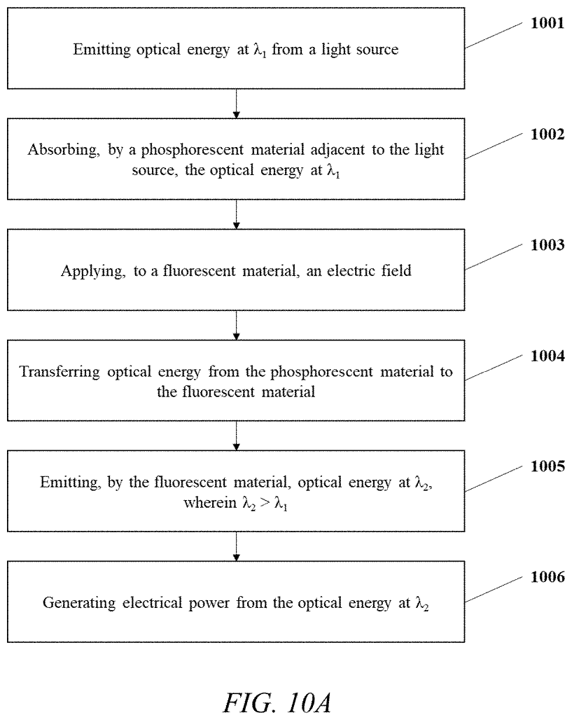

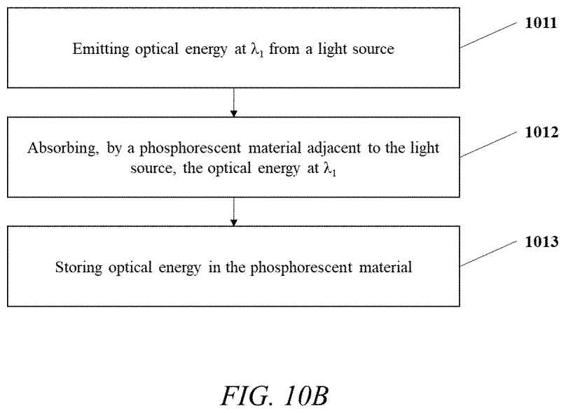

FIG. 10A illustrates a method of absorbing and releasing power from a photon battery. The method can comprise, at a first operation 1001, emitting optical energy at a first wavelength (e.g., λ₁) from a light source. The optical energy at the first wavelength can be emitted from a light-emitting surface of the light source. The light source can be an artificial light source, such as a LED, laser, or lamp. The light source can be a natural light source. The light source can be powered by an electric power source, such as another energy storage device (e.g., battery, supercapacitors, capacitors, fuel cells, etc.) or another power supply (e.g., electrical grid).

At a second operation 1002, a phosphorescent material that is adjacent to the light source can absorb the optical energy at the first wavelength. The optical energy may be directed from the light source to the phosphorescent material via a first waveguide. For example, the phosphorescent material can be adjacent to the light-emitting surface of the light source. In some instances, the first wavelength can be an ultraviolet wavelength (e.g., 20-400 nm).

At a third operation 1003, a stimulus may be applied to a fluorescent material that is in optical communication with the phosphorescent material. The stimulus may be an applied electric field. For example, an electric field may be applied to the fluorescent material by generating a voltage across the fluorescent material. The stimulus (e.g., the applied electric field) may alter an excitation spectrum of the fluorescent material. The stimulus may increase a spectral overlap between an emission spectrum of the phosphorescent material and the excitation spectrum of the fluorescent material.

At a next operation 1004, the optical energy is transferred from the phosphorescent material to the fluorescent material. In some instances, energy may be transferred by FRET, RET, or Dexter transfer. Energy transfer efficiency may increase in response to the stimulus applied at operation 1003. For example, an applied electric field may increase the spectral overlap between the emission spectrum of the phosphorescent material and the excitation spectrum of the fluorescent material, thereby increasing the efficiency of energy transfer by FRET or RET.

At a next operation 1005, after optical energy is transferred from the phosphorescent material to the fluorescent material, the fluorescent material can emit optical energy at a second wavelength (e.g., λ₂). In some instances, the first wavelength can be a visible wavelength (e.g., 400-700 nm). The second wavelength can be greater than the first wavelength. That is, the optical energy at the first wavelength can be at a higher energy level than the optical energy at the second wavelength. In some instances, the rate of absorption of the optical energy at the first wavelength by the phosphorescent material can be faster than the rate of emission of the optical energy at the second wavelength by the fluorescent material.

At a next operation 1006, a photovoltaic cell adjacent to an optical charging layer comprising the fluorescent material and the phosphorescent material can absorb the optical energy at the second wavelength that is emitted by the fluorescent material. The optical energy may be directed from the optical charging layer to the photovoltaic cell via a second waveguide. For example, a light-absorbing surface of the photovoltaic cell can absorb the optical energy at the second wavelength. In some instances, the photovoltaic cell can be tailored to absorb the wavelength or range of wavelengths that is emitted by the fluorescent material. In some instances, the light-absorbing surface of the photovoltaic cell can comprise one or more depressions defined by corresponding protrusions to allow for increased interfacial surface area between the phosphorescent material and the photovoltaic cell. The photovoltaic cell can convert the absorbed optical energy at the second wavelength and generate electrical power. In some instances, the electrical power generated by the photovoltaic cell can be used to power an electrical load that is electrically coupled to the photovoltaic cell. The electrical load can be an electronic device, such as a mobile phone, tablet, or computer. The electrical load can be a vehicle, such as a car, boat, airplane, or train. The electrical load can be a power grid. In some instances, at least some of the electrical power generated by the photovoltaic cell can be used to power the light source, such as when no electrical load is connected to the photovoltaic cell. In some instances, at least some of the electrical power generated by the photovoltaic cell can be used to charge a rechargeable battery (e.g., lithium ion battery), such as when no electrical load is connected to the photovoltaic cell. The rechargeable battery can in turn be used to power the light source. Beneficially, a photon battery assembly used in this method can be at least in part self-sustaining and prevent loss of energy from the system (e.g., other than from inefficient conversion of energy). For some batteries, the stored light may be used to directly pump a laser. Alternatively, electricity generated from the battery may be used to power a light source that may pump a laser.

FIG. 10B illustrates a method of storing energy in a photon battery. The method can comprise, at a first operation 1011, emitting optical energy at a first wavelength (e.g., λ₁) from a light source. The optical energy at the first wavelength can be emitted from a light-emitting surface of the light source. The light source can be an artificial light source, such as a LED, laser, or lamp. The light source can be a natural light source. The light source can be powered by an electric power source, such as another energy storage device (e.g., battery, supercapacitors, capacitors, fuel cells, etc.) or another power supply (e.g., electrical grid).

At a second operation 1012, a phosphorescent material that is adjacent to the light source can absorb the optical energy at the first wavelength. The optical energy may be directed from the light source to the phosphorescent material via a first waveguide. For example, the phosphorescent material can be adjacent to the light-emitting surface of the light source. In some instances, the first wavelength can be an ultraviolet wavelength (e.g., 20-400 nm).

At a next operation 1013, the optical energy is stored in the phosphorescent material. The optical energy may be stored in a triplet state, wherein energy transfer from the triplet state is slow as compared to energy transfer from an excited singlet state. Energy may be stored in the triplet state for later release. For example, energy stored in the triplet state may be later transferred to the fluorescent material as described in FIG. 10A and used to generate electrical power. Energy may be stored in the phosphorescent material for hours, days, or weeks. Energy storage efficiency may be insensitive to thermal changes.

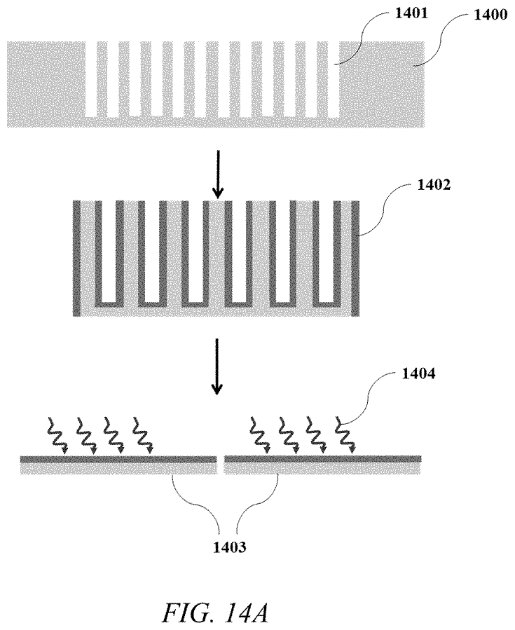

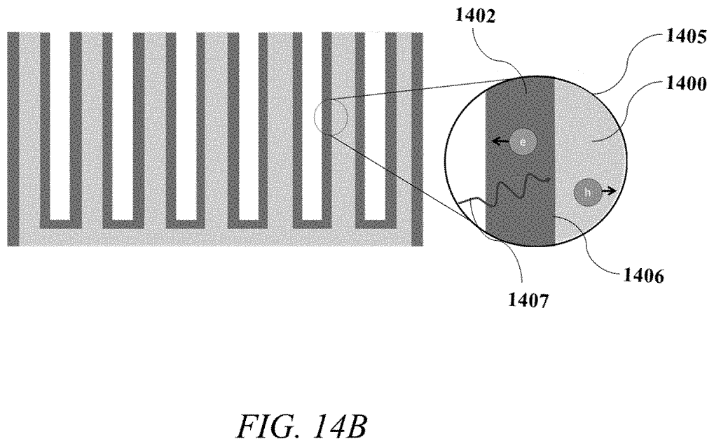

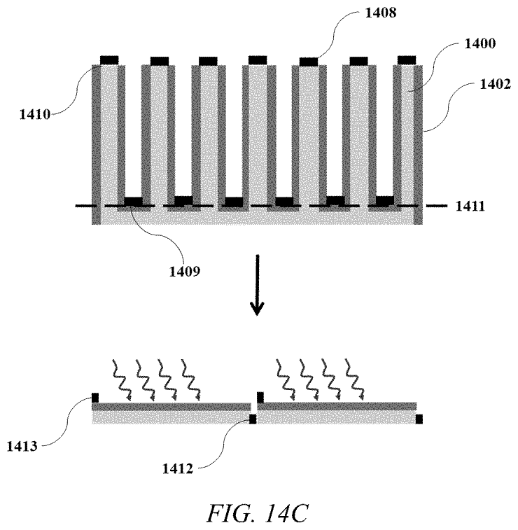

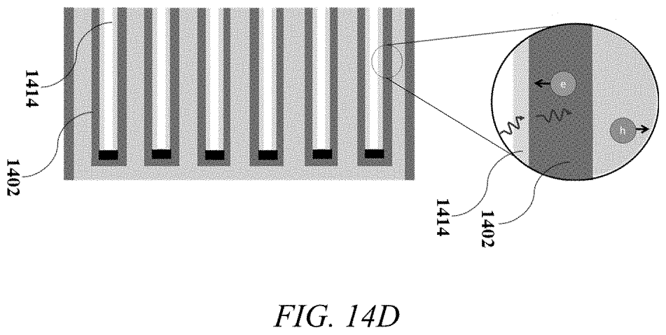

FIG. 14A illustrates a method for fabricating a photovoltaic panel. The top panel shows a wafer 1400 interspersed with trenches 1401. The trenches may be uniform, or comprise a variety of dimensions, surface profiles (e.g., sloped or vertical walls), and spacings. The wafer may comprise a semiconductor, such as a p-type silicon semiconductor. As is shown in the middle panel, the wafer may be coated with a second material 1402. This material may also comprise a semiconductor, and is often an n-type semiconductor (e.g., an n-type silicon semiconductor) applied to a p-type semiconductor wafer 1400. In some cases, such trenches (e.g., 1401) and other features of the photovoltaic panel may form the basis of, or integrate with, features of the optical charging layer that optimize separation of the phosphorescent and fluorescent materials of the present disclosure. For example, an optical charging layer may be patterned on top of the second material 1402, such as by separate applications of a phosphorescent material and a fluorescent material over different portions of the surfaces. The optical charging later may also be patterned along with a removable layer (e.g., photoresist or an etchable metallization layer), whereby the removal layer imparts a separation between the phosphorescent and fluorescent materials. As is illustrated in the bottom panel, the walls may be diced and laid flat to create a photovoltaic panel 1403 capable of generating current upon excitation by light 1404.

FIG. 14B illustrates the coated wafer from the middle panel in FIG. 14A, providing a zoomed in depiction 1405 of current generation at the junction 1406 between the two materials 1400 and 1402. The coating of the second material may be sufficiently thin to allow light 1407 to penetrate to the junction 1406 of the two materials, causing electrons to flow from the n-type material to the p-type material and creating a potential which may be used to generate current or charge a battery.

As is depicted in the top panel of FIG. 14C, prior to dicing, metal contact layers 1408 may be applied to the bottom of the trenches 1409 and tops of the walls 1410. Alternatively, the metal contact layer may be solely applied to the bottom of the trenches or the top portions of the walls. A metal contact layer applied to the top of a wall may cover the entire space (the top of the wafer material and the second material), or just the wafer material. Confining a metal contact layer on the top of a wall to just the wafer can prevent conductive contact between the wafer material and second material, thereby preventing metal contact layer mediated relaxation or discharge by the fabricated photovoltaic. The walls may be diced along a plane 1411 above the layers of the second material at the bottom of the trenches. As is shown in the bottom panel, the metal contact layers disposed on the sides of the photovoltaic panels 1412 (previously the tops of the walls 1410) may be used to connect separate photovoltaic panels. The metal contact layers disposed on the second material layers 1413 may connect the photovoltaic panel to extrinsic circuits or devices.

As is shown in FIG. 14D, a layer of antireflective coating 1414 may be applied on top of the second material 1402. This may improve the efficiency of the device by increasing photon flux into the second material, thereby allowing the photovoltaic to absorb and convert (e.g., into a current or a potential) a greater proportion of incident light energy. The antireflective coating may comprise silica, tantalum oxide, aluminum oxide, silicon nitride, magnesium fluoride, hafnium dioxide, or any combination thereof.

A photon battery assembly may comprise a non-linear optical component. The non-linear optical component may perform harmonic generation. A non-linear optical component may combine two or more incident photons to produce a higher frequency photon, such as by sum-frequency generation, difference-frequency generation, second-harmonic generation, or resonant frequency doubling. The non-linear optical component may combine two incident photons with the same frequency to produce a single photon with double the frequency. The non-linear optical component may combine two incident photons with different frequencies to produce a higher frequency photon. The non-linear optical component may comprise a bandwidth of 1 nm, 2 nm, 3 nm, 4 nm, 5 nm, 6 nm, 8 nm, 10 nm, 15 nm, 20 nm, 30 nm, 40 nm, 50 nm, 75 nm, 100 nm, 150 nm, or more. The non-linear optical component may produce light with a bandwidth of 1 nm, 2 nm, 3 nm, 4 nm, 5 nm, 6 nm, 8 nm, 10 nm, 15 nm, 20 nm, 30 nm, 40 nm, 50 nm, 75 nm, or more. For example, a non-linear optical component may perform sum-frequency generation utilizing two photons with frequencies of 900±50 nm. The non-linear optical component may utilize incoherent light (e.g., sunlight). The non-linear optical component may comprise a doubling crystal or a tripling crystal.

The non-linear optical component may also comprise an up-conversion luminescent or phosphorescent material. An up-conversion material may absorb light of a first wavelength and emit light with a shorter wavelength. For example, an up-conversion luminescent or phosphorescent material may absorb infrared light and emit visible light. An up-conversion luminescent or phosphorescent material may comprise anisotropic absorption and emission profiles. An up-conversion luminescent or phosphorescent material may be embedded within an optical charging layer, or may be disposed as a separately from the optical charging layer. An up-conversion luminescent or phosphorescent material may comprise a trivalent rare earth ion (e.g., Tm³⁺, Er³⁺, or Yb³⁺), for example YNbO4:Er³⁺/Yb³⁺.

The non-linear optical component may allow a battery to utilize lower frequency light than is required to excite its phosphorescent materials. In such cases, a non-linear optical component may increase the energy of incident photons from the light source (e.g., FIG. 1, 101), thereby producing usable (e.g., capable of exciting a phosphorescent material) photons. One application for this effect is for the transformation of fiber optic transmitted light. In part owing to its high transmissivity through a range of materials, including many fiber optics, red and infrared light are commonly used for signal and energy transmission. While red and infrared light are often insufficient for exciting phosphorescent materials, the light may be transformed (e.g., into blue, violet, or ultraviolet light) that is better suited for some of the batteries disclosed herein. Among many potential applications, this may enable wireless charging, for example by placing the battery on a pad that transmits red light.

Sum-frequency generation may also be used to increase the efficiency of a device that harvests sunlight. Sunlight typically comprises a greater proportion of low frequency visible light (e.g., green, yellow, orange, and red light) than high frequency visible light (e.g., purple light) that is typically better suited for exciting phosphorescent materials. Therefore, a battery may perform sum-frequency generation to increase high energy photon flux from sunlight.

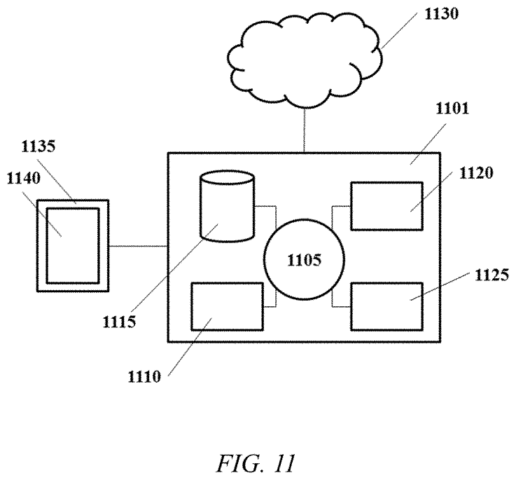

FIG. 11 shows a computer control system. The present disclosure provides computer control systems that are programmed to implement methods of the disclosure. A computer system 1101 is programmed or otherwise configured to regulate one or more circuitry in a photon battery assembly, in accordance with some embodiments discussed herein. For example, the computer system 1101 can be a controller, a microcontroller, or a microprocessor. In some cases, the computer system 1101 can be an electronic device of a user or a computer system that is remotely located with respect to the electronic device. The electronic device can be a mobile electronic device. The computer system 1101 can be capable of sensing the connection(s) of one or more electrical loads with a photon battery assembly, the connection(s) of one or more rechargeable batteries with a photon battery assembly, and/or the connection(s) of a photovoltaic cell and a light source within a photon battery assembly. The computer system 1101 may be capable of managing the inflow and/or outflow of power from each or a combination of photon battery assemblies electrically connected in series or in parallel, and in some cases, individually or collectively electrically communicating with a power source and/or an electrical load. The computer system 1101 may be capable of computing a rate off of power from the photon battery and/or a rate of consumption of power by an electrical load. For example, the computer system may be based on such computation, determine whether and how to direct power discharged from a photovoltaic cell to a light source, an external battery (e.g., lithium ion battery), and/or an electrical load. The computer system may be capable of adjusting or regulating a voltage or current of power input and/or power output of the photon battery. The computer system 1101 may be capable of adjusting and/or regulating different component settings. For example, the computer system may be capable of adjusting or regulating a brightness, intensity, color (e.g., wavelength, frequency, etc.), pulsation period, or other optical characteristics of a light emitted by a light source in the photon battery assembly. For example, the computer system may be configured to adjust a light emission setting from a light source depending on the type of phosphorescent material or fluorescent material used in the photon battery.

For example, the computer system 1101 can be capable of regulating different charging and/or discharging mechanisms of a photon battery assembly. The computer system may turn on an electrical connection between a light source and a power supply to start charging the photon battery assembly. The computer system may turn off an electrical connection between the light source and the power supply to stop charging the photon battery assembly. The computer system may turn on or off an electrical connection between a photovoltaic cell and an electrical load. In some instances, the computer system may be capable of detecting a charge level (or percentage) of the photon battery assembly. The computer system may control the application or removal of a stimulus (e.g., an electric field), thereby controlling a transition between storing or releasing optical energy. The computer system may be capable of determining when the assembly is completely charged (or nearly completely charged) or discharged (or nearly completely discharged). In some instances, the computer system may be capable of maintaining a certain range of charge level (e.g., 5%-95%, 10%-90%, etc.) of the photon battery assembly, such as to maintain and/or increase the life of the photon battery assembly, which complete charge or complete discharge can detrimentally shorten. In some embodiments, the computer system may alter the stimulus in response to a certain range of charge level. For example, the computer system may apply a stimulus, thereby releasing optical energy, when the photon battery assembly is above a certain charge level (e.g., above ˜50%, above ˜60%, above ˜70%, above ˜80%, above ˜90%, or above ˜95%). In some instances, the computer system may remove a stimulus, thereby storing optical energy, when the photon battery assembly is below a certain charge level (e.g., below ˜50%, below ˜40%, below ˜30%, below ˜20%, below ˜10%, or below ˜5%).

The computer system 1101 includes a central processing unit (CPU, also “processor” and “computer processor” herein) 1105, which can be a single core or multi core processor, or a plurality of processors for parallel processing. The computer system 1101 also includes memory or memory location 1110 (e.g., random-access memory, read-only memory, flash memory), electronic storage unit 1115 (e.g., hard disk), communication interface 1120 (e.g., network adapter) for communicating with one or more other systems, and peripheral devices 1125, such as cache, other memory, data storage and/or electronic display adapters. The memory 1110, storage unit 1115, interface 1120 and peripheral devices 1125 are in communication with the CPU 1105 through a communication bus (solid lines), such as a motherboard. The storage unit 1115 can be a data storage unit (or data repository) for storing data. The computer system 1101 can be operatively coupled to a computer network (“network”) 1130 with the aid of the communication interface 1120. The network 1130 can be the Internet, an internet and/or extranet, or an intranet and/or extranet that is in communication with the Internet. The network 1130 in some cases is a telecommunication and/or data network. The network 1130 can include one or more computer servers, which can enable distributed computing, such as cloud computing. The network 1130, in some cases with the aid of the computer system 1101, can implement a peer-to-peer network, which may enable devices coupled to the computer system 1101 to behave as a client or a server.

The CPU 1105 can execute a sequence of machine-readable instructions, which can be embodied in a program or software. The instructions may be stored in a memory location, such as the memory 1110. The instructions can be directed to the CPU 1105, which can subsequently program or otherwise configure the CPU 1105 to implement methods of the present disclosure. Examples of operations performed by the CPU 1105 can include fetch, decode, execute, and writeback.

The CPU 1105 can be part of a circuit, such as an integrated circuit. One or more other components of the system 1101 can be included in the circuit. In some cases, the circuit is an application specific integrated circuit (ASIC).

The storage unit 1115 can store files, such as drivers, libraries and saved programs. The storage unit 1115 can store user data, e.g., user preferences and user programs. The computer system 1101 in some cases can include one or more additional data storage units that are external to the computer system 1101, such as located on a remote server that is in communication with the computer system 1101 through an intranet or the Internet.

The computer system 1101 can communicate with one or more local and/or remote computer systems through the network 1130. For example, the computer system 1101 can communicate with all local energy storage systems in the network 1130. In another example, the computer system 1101 can communicate with all energy storage systems within a single assembly, within a single housing, and/or within a single stack of assemblies. In other examples, the computer system 1101 can communicate with a remote computer system of a user. Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 1101 via the network 1130.

Methods as described herein can be implemented by way of machine (e.g., computer processor) executable code stored on an electronic storage location of the computer system 1101, such as, for example, on the memory 1110 or electronic storage unit 1115. The machine executable or machine readable code can be provided in the form of software. During use, the code can be executed by the processor 1105. In some cases, the code can be retrieved from the storage unit 1115 and stored on the memory 1110 for ready access by the processor 1105. In some situations, the electronic storage unit 1115 can be precluded, and machine-executable instructions are stored on memory 1110.

The code can be pre-compiled and configured for use with a machine having a processor adapted to execute the code, or can be compiled during runtime. The code can be supplied in a programming language that can be selected to enable the code to execute in a pre-compiled or as-compiled fashion.

Aspects of the systems and methods provided herein, such as the computer system 1101, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 1101 can include or be in communication with an electronic display 1135 that comprises a user interface (UI) 1140 for providing, for example, user control options (e.g., start or terminate charging, start or stop powering an electrical load, route power back to self-charging, etc.). Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 1105. The algorithm can, for example, change circuitry of a photon battery assembly or a stack of photon battery assemblies based on, for example, sensing the connection(s) of one or more electrical loads with a photon battery assembly, the connection(s) of one or more rechargeable batteries with a photon battery assembly, and/or the connection(s) of a photovoltaic cell and a light source within a photon battery assembly. The algorithm may be capable of managing the inflow and/or outflow of power from each or a combination of photon battery assemblies electrically connected in series or in parallel, and in some cases, individually or collectively electrically communicating with a power source and/or an electrical load.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

What is claimed is:

1. A photon battery comprising:
an optical charging layer comprising (i) phosphorescent material configured to absorb photonic energy from a light source and (ii) fluorescent material configured to conditionally accept energy from the phosphorescent material and emit fluorescence in response to an applied stimulus; and
an optical charging layer comprising a photovoltaic cell configured to convert the fluorescence into electrical energy.

2. The photon battery of claim 1, further comprising the light source.

3. The photon battery of claim 1, wherein the phosphorescent material comprises a phosphor grain.

4. The photon battery of claim 1, wherein the phosphorescent material comprises a film or wafer with a maximum thickness of 2 millimeters.

5. The photon battery of claim 1, wherein the fluorescent material comprises a quantum dot.

6. The photon battery of claim 1, wherein the fluorescent material comprises a quantum nano rod.

7. The photon battery of claim 1, wherein the fluorescent material comprises a quantum well.

8. The photon battery of claim 1, wherein the fluorescent material coats or surrounds the phosphorescent material.

9. The photon battery of claim 1, further comprising a light guide configured to direct the photonic energy from the light source to the optical charging layer.

10. The photon battery of claim 1, wherein the stimulus comprises application of an electric field.

11. The photon battery of claim 1, wherein the stimulus comprises application of a magnetic field.

12. The photon battery of claim 1, wherein the stimulus comprises a temperature change.

13. The photon battery of claim 1, wherein the stimulus comprises an applied voltage.

14. The photon battery of claim 1, further comprising a non-linear optical component disposed between the light source and the optical charging layer.

15. The photon battery of claim 14, wherein the non-linear optical component is configured to perform sum-frequency generation.

16. The photon battery of claim 1, wherein the phosphorescent material comprises an anisotropic phosphor emitter.

17. The photon battery of claim 1, wherein the phosphorescent material comprises a crystal lattice comprising a plurality of phosphors that occupy a specific lattice site.

18. A method for discharging a photon battery, comprising applying said stimulus to said photon battery of claim 1.

19. The method of claim 18, wherein the stimulus is differentially applied to different portions of the optical charging layer.

20. The method of claim 19, wherein the stimulus produces an image.

21. The method of claim 20, wherein the image comprises at least 400 pixels.

22. The method of claim 21, wherein the at least 400 pixels each comprises a width of at least 30 nanometers (nm).
